(19) United States
(12) Patent Application Publication
(10) Pub. No.: US 2012/0108438 A1
(43) Pub. Date: May 3, 2012

(54) SUPERCONDUCTORS AND METHODS OF MANUFACTURING THE SAME

(76) Inventor: Sze Kui Ng, Hong Kong (CN)

(21) Appl. No.: 13/253,091

(22) Filed: Oct. 5, 2011

Related U.S. Application Data
(60) Provisional application No. 61/408,701, filed on Nov. 1, 2010.

(51) Int. Cl. H01L 39/24; H01B 13/00

(52) U.S. Cl. 505/433; 505/470; 505/450; 505/472; 427/62; 427/596; 148/96

(57) ABSTRACT

A method of manufacturing superconductors with critical temperature T_{c}>300K is disclosed. This method is from a theory of high-T_{c} superconductivity wherein the doping mechanism is found. A kind of superconductors composed by this method is the AlB₂-type superconductors obtained by doping AlB₂-type intermetallics such as Sr₁₋ₓCaₓGa₂. Another kind of superconductors composed by this method is the CaCu₅-type superconductors obtained by doping CaCu₅-type intermetallics such as L₁₋ₓAₓCu₅, LCu₅₍₁₀ₓ₎Ni₅ₓ(A-Ca, Sr; L-La, Y, Mm,), Sr₁₋ₓCaₓCu₅, La₁₋ₓSr_{x(1-y)}CaₓCu₅. In particular the CaCu₅-type intermetallics LaNi₅ and MmNi₅ are superconductors with critical temperature T_{c}>300K. These CaCu₅-type superconductors are with high critical current densities and thus are applicable for the transmission of electricity.

### CROSS-REFERENCE TO RELATED APPLICATIONS

This application claims the benefit of provisional patent application Ser. No. 61/408,701, filed Nov. 1, 2010 by the present inventor.

### REFERENCES CITED

### U.S. Patent Documents

U.S. Pat. No. 5,082,825 Hermann August 1988.
U.S. Pat. No. 7,132,288 Maeda et al. January 1989.
U.S. Pat. No. 5,578,551 Chu et al. November 1996.
U.S. Pat. No. 6,956,011 Akimitsu et al., October 2005.

### Other Publications

J. G. Bednorz and K. A. Muller, Zeitschrift fr Phsik, B64, 189 (1986).
H. Maeda, et al., J. App. Phys. 27, L209 (1988).
Z. Z. Sheng and A. M. Hermann, Nature, 332, 55 (1988).
A. Schilling, et al., Nature, 363, 56 (1993).
L. Gao, et al., Phys. Rev. B, 50, 4260 (1994).
S. K. Ng, 26th Conf. on Low Temperature Physics, Beijing, 2011; arXiv math/0004151v3.
R. J. Cava, et al., Phys. Rev. Lett., 58, 408 (1987).
W. Y. Liang, et al., J. Phys.: Condens. Matter, 10, 11365 (1998).
J. Nagamatsu, et al., Nature, 410, 63 (2001); I. Felner, arXiv cond-mat/0102508.
A. Y. Liu, et al., PRL, 87, 0870051(2001); X. K. Chan, et al., PRL, 87,1570021 (2001).
L. H. Bennett, R. E. Watson, in Theory of Alloy Phase Formation, (1980).
M. Imai, et al., Phys. Rev. Lett., 87, 077003 (2001).
C. Zheng and R. Hoffmann, Inorg. Chem., 28, 1074 (1989).
D. J. Chakrabari and D. E. Laughlin, Bull. Alloy Phase Diagram, 2, 319 (1981).
P. R. Subramanian and D. E. Laughlin, Bull. Alloy Phase Diagram, 9, 316 (1988).

### FIELD OF THE INVENTION

This invention is related to the field of high critical temperature T_{c} superconductivity and applications.

### BACKGROUND OF THE INVENTION

A class of superconductors, henceforth referred to as the high-T_{c} superconductors, was first discovered by Bednorz and Muller and disclosed in the article “Possible High-T_{c} Superconductivity in the BaLaCuO System, Zeitschrift fr Phsik, B64, 189 (1986)”. Since then several kinds of this class of superconductors of the cuprate type have been discovered. The Bi-based cuprate with critical temperature T_{c}≈105K was disclosed in “H. Maeda, et al., J. App. Phys. 27, L209 (1988)” and in “U.S. Pat. No. 7,132,288, Maeda et al. January 1989”, The Tl-based cuprate with T_{c}≈125K was disclosed in “Z. Z. Sheng and A. M. Hermann, Nature, 332, 55 (1988)” and in “U.S. Pat. No. 5,082,825 Hermann August 1988”. The Hg-based cuprate with T_{c}≈135K was disclosed in “A. Schilling, et al., Nature, 363, 56 (1993)” and in “L. Gao, et al., Phys. Rev. B, 50, 4260 (1994)” and in “U.S. Pat. No. 5,578,551 Chu et al. November 1996”. Up to now the highest critical temperature T_{c} is about 164K for Hg-based cuprate under high pressure. Now a main aim of the field of superconductivity is to understand the mechanism of the high-T_{c} superconductivity and to find high-T_{c} superconductors with the critical temperature T_{c}>300K.

Recently a quantum gauge model of high-T_{c} superconductivity is presented by the inventor (c.f. Sze Kui Ng, Gauge model of high-T_{c} superconductivity, the 26th Conference on Low Temperature Physics, Beijing, August 2011, and Sze Kui Ng, arXiv:math/0004151v3). This model unifies the electron-electron interaction and the electron-phonon interaction for the forming of Cooper pairs of electrons of superconductivity. In this gauge model, there is a seagull vertex term:

$$- \frac{1}{ih + κ} {e}_{0}^{2} {Z}^{*} {ZA}^{2}$$

where the complex variable Z represents an electron (Z* is the complex conjugate of Z), the real variable A represents the photon gauge field, and

$$\frac{1}{ih + κ}$$

is a parameter where h is an energy parameter proportional to the Planck constant and the parameter κ=k_{B}T where k_{B} is the Boltzmann constant and T is the absolute temperature, and e₀ is the (bare) electric charge. In this gauge model, while there is a term of order e₀ gives the usual repulsive Coulomb potential of order e₀² between electrons, this seagull vertex term of order e₀² gives a small attractive potential of order e₀⁴ between electrons. Since for a crystal material the repulsive Coulomb potential between electrons is balanced by the attractive potential from phonons (or protons) interacting with electrons, this small attractive potential can be used as an additional electron-electron interaction for the forming of Cooper pairs of electrons. By a renormalization group method, this gauge model gives a unified description of superconductivity and magnetism including antiferromagnetism, pseudogap phenomenon, paramagnetic Meissner effect, Type I and Type II supeconductivity and high-T_{c} superconductivity. In this gauge model, the doping mechanism of superconductivity is found. It is shown that the critical temperature T_{c} is related to the ionization energies of elements and can be computed by a formula of T_{c}. For the high-T_{c} superconductors such as La₂₋ₓSrₓCuO₄, YBa₂Cu₃O₇, and MgB₂, the computational results of T_{c} agree with the experimental results.

In this gauge model of high-T_{c} superconductivity the inventor show that the phase of high-T_{c} superconductivity (and the conventional Type II superconductivity) appears at the phase line h²=3 κ². It is shown that for a fixed κ the increasing of the doping parameter x of the cuprates such as La₂₋ₓSrₓCuO₄ gives the increasing of h. Thus the phase plane (κ, h) of phase diagram corresponds to the phase plane (T, x) of phase diagram of superconductors such as La₂₋ₓSrₓCuO₄. It is shown that this increasing of h by the increasing of x gives the doping mechanism of high-T_{c} superconductivity.

In this gauge model of high-T_{c} superconductivity we have the following nontrivial fixed point of the renormalization group equation:

$${r}^{*} = {B}^{- \frac{2}{3}} \frac{{( 1 - {b}^{ε} )}^{\frac{2}{3}} [ {b}^{2} - 1 + \frac{{CB}^{2} {b}^{2} + 2 ε}{{( 1 - {b}^{ε} )}^{2}} ]}{{Ab}^{4 + \frac{2}{3} ε}} \\ {u}^{*} = {B}^{- 2} \frac{{{( 1 - {b}^{ε} )}^{2} [ {b}^{2} - 1 + \frac{{CB}^{2} {b}^{2} + 2 ε}{{( 1 - {b}^{ε} )}^{2}} ]}^{\frac{3}{2}}}{{A}^{\frac{3}{2}} {b}^{3 + 3 ε}} \qquad ( 1 )$$

where A, B, C are coefficients in terms of the factor (ih+κ)⁻¹, ε>0 is a parameter which is analogous to the ε in the e-expansion of the Ginzburg-Landau model of superconductivity in statistical physics. As analogous to the GL model the parameter ε is related to the dimension of the space that d=3−ε is the (fractional) dimension of the space, and is related to the ultraviolet limit; and the parameter b is related to the infrared limit.

From the fixed point (1) we have two cases. The Case 1) is with 0<ε<<1 which gives the three dimensional (3D) Type I and Type II conventional superconductivity while the Case 2) is with ε=1 which gives the quasi-2D high-T_{c} superconductivity. From the expansion of the factor 2⁶CB²=(ih+ε)⁻¹² in (1), the phase plane (T, x) of the phase diagram of high-T_{c} superconductivity is derived.

### SUMMARY OF THE INVENTION

A method of composing superconductors with the critical temperature T_{c}>300K is disclosed. This method is from the abovementioned gauge model of high-T_{c} superconductivity wherein the doping mechanism of superconductivity is found. A class of superconductors composed by this method is the class of intermetallics with a hexagonal crystal structure consisting of three layers wherein the middle layer is as the conducting layer.

A kind of superconductors with hexagonal crystal structure composed by this method is the AlB₂-type intermetallic superconductors which are obtained by doping the AlB₂-type intermetallics such as A₁₋ₓCaₓCa₂ (0.1≦x≦0.9) wherein A=Sr, Ba.

A kind of superconductors with hexagonal crystal structure composed by this method is the AlB₂-type intermetallic superconductors which are obtained by doping the AlB₂-type intermetallics such as Sr₁₋ₓAₓAlSi (0.1≦x≦0.9) wherein A=Ca, Ba.

A kind of superconductors with hexagonal crystal structure composed by this method is the AlB₂-type intermetallic superconductors which are obtained by doping the AlB₂-type intermetallics such as La₁₋ₓBaₓCuGe and Gd₁₋ₓCaₓCuSi (0.02≦x≦1).

A kind of superconductors with hexagonal crystal structure composed by this method is the CaCu₅-type intermetallic superconductors which are obtained by doping CaCu₅-type intermetallics such as La₁₋ₓAₓCu₅, Y₁₋ₓAₓCu₅, Gd₁₋ₓAₓCu₅, Mm₁₋ₓAₓCu₅, (A=Ca, Sr, Mm denotes Mischmetal), LCu₅₍₁₋ₓ₎Ni₅ₓ(L=La, Y, Mm, 0.02≦x≦1), and Sr₁₋ₓCaₓCu₅ (0.01≦x≦0.9), and La₁₋ₓSr_{x(1-y)}Ca_{xy}Cu₅ (0.01≦x,y≦0.9), In particular the CaCu₅-type intermetallics LaNi₅ and MmNi₅ are superconductors with the critical temperature T_{c}>300K.

It is shown that the CaCu₅-type intermetallic superconductors are with high critical current densities and thus they are applicable for the transmission of electricity.

### DESCRIPTION OF DRAWINGS

FIG. 1 shows the (T, x) phase diagram of high-T_{c} superconductors such as La₂₋ₓSrₓCuO₄. This phase diagram is derived from the abovementioned gauge model of high-T_{c} superconductivity and the well known experimental (T, x) phase diagram of La₂₋ₓSrₓCuO₄ in “R. J. Cava, et al., Phys. Rev. Lett., 58, 408 (1987)” and “W. Y. Liang, et al., J. Phys.: Condens. Matter, 10, 11365 (1998)”.

In this phase diagram the parameter κ corresponds to T by the relation is κ=k_{B}T. The line a denotes the phase line κ²=3h² (of the phase plane (κ, h)) in the phase plane (T, x). The line b denotes the cross-over line κ²=h² (of the phase plane (κ, h)) in the phase plane (T, x). The line c denotes the phase line h²=3 κ² (of the phase plane (κ, h)) of superconductivity in the phase plane (T, x). Then the line d denotes the cross-over line h²=(2+\sqrt{3})²κ² (of the phase plane (κ, h)) in the phase plane (T, x). In this phase diagram the original phase line h²=3 κ² with the part denoted by the dash line is bifurcated into the phase line h²=3 κ² denoted by the line c in the phase plane (T, x).

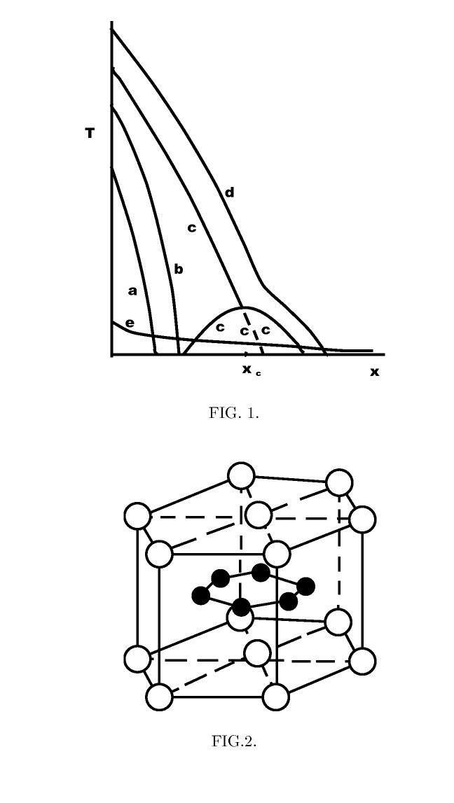

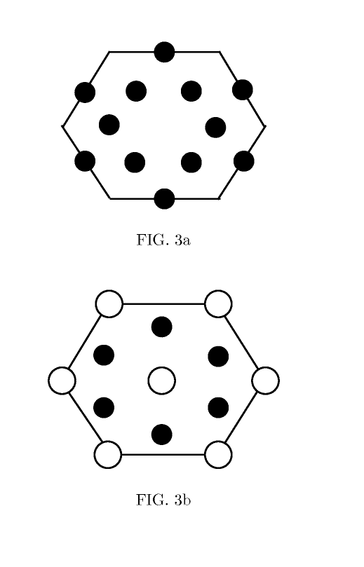

The two lines a and c are the two basic phase lines for antiferromagnetism and superconductivity respectively. In this phase diagram we have two more phase lines b and d. The region between a and b is the region of spin density waves and region of insulator. The region between b and c is the region of charge density waves and region of semiconductivity. The region between a and c is usually called the region of pseudogap. The region between c and d is the region of paramagnetic Messiner effect and is usually called the region of non-Fermi liquid (We may also call this region as the extended region of pseudogap). The right side of d is the region of normal metallic state. Then the bifurcation of the phase line c gives the region of high-T_{c} superconductivity. Then the left side of a is the region of antiferromagnetism (The region of antiferromagnetism is also obtained by the bifurcation of the phase line a where a part of this region of antiferromagnetism obtained by bifurcation is at the outside of this phase diagram in FIG. 1).

Then let us consider the special phase line e. This phase line e is the cross-over line from the phase of two dimensional phenomenon (i.e. the Case 2) with ε=1) to the phase of three dimensional phenomenon (i.e. the Case 1) with 0<ε<<1). Above this line is the phase of two dimensional (2D) phenomenon and below this line is the phase of three dimensional (3D) phenomenon. In the 2D phase the region in the bifurcation region of superconductivity is the region of high-T_{c} superconductivity and in the 3D phase the region in the bifurcation region of superconductivity is the region of conventional Type II superconductivity. In the 3D phase the region between the line c and the line d is the region of Type I superconductivity (In the 2D phase this region between the line c and the line d is the extended region of pseudogap).

Thus this phase diagram in FIG. 1 is a complete phase diagram on magnetism and superconductivity that it includes the Type I superconductivity, the conventional Type II superconductivity and the high-T_{c} superconductivity. The existence of the 3D phase in this phase diagram is important for the 2D phase high-T_{c} superconductivity since the existence of the 3D Type II superconductivity gives the stable existence of the 2D high-T_{c} superconductivity. This existence of the 3D Type II superconductivity is as the reservoir for the stable existence of the 2D high-T_{c} superconductivity.

FIG. 2 shows a hexagonal unit cell of MgB₂ of the AlB₂-type. The B atoms are depicted by the black balls and the Mg atoms are depicted by the white balls. When Mg is replaced by CaₓSr₁₋ₓ and B is replaced by Ga, it also shows a unit cell of CaₓSr₁₋ₓGa₂ of the AlB₂-type. Also when Mg is replaced by Sr₁₋ₓCaₓ and B₂ is replaced by AlSi, it shows a unit cell of Sr₁₋ₓCaₓAlSi of the AlB₂-type. Further when Mg is replaced by R₁₋ₓAₓ and B₂ is replaced by CuG where R═La, Gd and A=Ca.Sr, Ba and G=Si, Ge, it shows a unit cell of R₁₋ₓAₓCuG of the AlB₂-type.

FIG. 3 shows two layers of the unit cell of La₁₋ₓCaₓCu₅ of the CaCu₅-type. This unit cell is with the hexagonal crystal structure of three layers. FIG. 3a is the middle layer of the hexagonal crystal structure and FIG. 3b is the lower or upper layer of the hexagonal crystal structure. The Cu atoms are depicted by the black balls and the La(Ca) atoms are depicted by the white balls.

### DESCRIPTION OF PREFERRED EMBODIMENTS

In this gauge model of high-T_{c} superconductivity the doping mechanism of superconductivity is found. Also a method of computation of critical temperature T_{c} of superconductors is found. In particular the doping mechanism of superconductivity and the computation of the T_{c} of the intermetallic MgB₂ (U.S. Pat. No. 6,956,011 Akimitsu et al., October 2005) are given. This intermetallic MgB₂ is of the hexagonal AlB₂-type crystal structure. In this invention we extend the doping mechanism of superconductivity and the computation of T_{c} of MgB₂ to other intermetallics. To this end let us first consider the intermetallic Mg₁₋ₓBeₓB₂ (0≦x≦1). This intermetallic is of the AlB₂-type. For the doping mechanism of superconductivity of this intermetallic, let us consider the following function:

f(x)=737.7(1−x)+899.5x (2)

where 737.7 kJ/mol and 899.5 kJ/mol are approximately the first ionization energies of Mg and Be respectively. This function gives the relation that the increasing of x gives the increasing of h. We have 737.7<800.6<899.5 where 800.6 kJ/mol is the first ionization energy of B. Let us set the following relation (A main point is that 800.6−737.7 is small):

f(x₀)=737.7(1−x₀)+899.5x₀=800.6 (3)

for some x₀ (0<x₀<1). When (3) holds (or approximately holds), the channel connecting the two states of first ionization energy of B and Mg is opened (We notice that the relation (3) gives the degeneration of electron states. The resulting degenerate state gives a Jahn-Teller electron-phonon interaction effect which is described as a channel opening. Let us call (3) and the resulting Jahn-Teller effect of degeneration as the degenerate state of channel opening). This channel opening gives a freedom of electrons of B with a direction orthogonal to the B plane. By this freedom of electric current, the electrons of a cluster of B atoms in a unit cell can be coupled to the electrons of cluster of B atoms in another unit cell to form Cooper pairs. In this way the Cooper pairs of s-valence (and nonvalence) electrons of B, the Cooper pairs of s-valence electrons of Mg can be formed (In other words, through this channel opening the s-valence (or nonvalence) electrons of B and s-valence electrons of Mg can transit from the valence (or nonvalence) band to the conduction band from which Cooper pairs of these electrons can be formed by the attractive electron-electron interaction from the seagull vertex term). Thus this channel opening gives the 3D region (π-band) of conventional superconductivity. From this 3D conventional superconductivity we have the existence of quasi-2D bifurcation region (σ-band) of high-T_{c} superconductivity given by the B plane. We notice that x₀≈0. This agrees with the experiment that the state of superconductivity of Mg₁₋ₓBeₓB₂ is in the doping range 0≦x<1 and that MgB₂ is in the state of superconductivity (c.f. J. Nagamatsu, et al., Nature, 410, 63 (2001); I. Felner, arXiv: cond-mat/0102508). When (3) approximately holds, the s-valence electrons of B are in the state of first ionization energy of B. Then the s-nonvalence electrons of B are in the state of second ionization energy of B. Also the s-valence electrons of Mg are in the state of first ionization energy of Mg. The s-valence electrons of B and Mg in the state of first ionization energy are in the opened channel of 3D superconductivity while the s-nonvalence electrons of B in the state of second ionization energy of B are for the quasi-2D high-T_{c} superconductivity of the B plane. Thus the maximum value of the energy parameter |h_{B1}| and |h_{B2}| of the s-valence and nonvalence electrons of B are proportional to the first and second ionization energies of B respectively, and the maximum value of the energy parameter |h_{Mg}| of the s-valence electrons of Mg is proportional to the first ionization energy of Mg. Then, from the state of superconductivity h²=3 κ² we have the following formula of T_{c} of MgB₂:

$${k}_{B} {T}_{c} = κ = \frac{1}{\sqrt{3}} {Δ}_{MgB 2} \qquad ( 4 )$$

where Δ_{MgB2}=h=6|h_{B1}|+6|h_{B2}|+|h_{Mg}| is the energy gap of superconductivity of MgB₂, where

$$6 = \frac{12}{2}$$

is from the 12 valence of nonvalence s-electrons of the B atoms in a hexagonal unit cell of MgB₂. From the table of ionization energies, the first and second ionization energies of B are approximately equal to 800.6 kJ/mol and 2427.1 kJ/mol. Let |h_{B1}|≈ξ800.6 kJ/mol and |h_{B2}≈ξ2427.1 kJ/mol, |h_{Mg}|≈ξ737.7 kJ/mol where ξ≈2.83133971·10⁻⁵ is a proportional constant determined from the computation of T_{c} of Nb. Then from (4) we have:

T_{c}≈39.53K (Computed value of T_{c} of MgB₂) (5)

This agrees with the experimental value of T_{c}≈39K of MgB₂. We notice that the energy gap Δ_{MgB2}=h=6|h_{B1}|+6|h_{B2}|+|h_{Mg}| contains the sum of two energy gaps Δ₁=6|h_{B1}| and Δ₂=6|h_{B2}|. We have that Δ₁ correspond to the conventional 3D superconductivity and Δ₂ correspond to the quasi-2D high-T_{c} superconductivity. Thus we have the two-gap superconductivity. This agrees with the phenomenon of two-gap superconductivity of MgB₂ (c.f. A. Y. Liu, et al., Phys. Rev. Lett., 87, 0870051 (2001); X. K. Chan, et al., Phys. Rev. Lett., 87, 1570021 (2001)). In the following examples the principle of the doping mechanism of superconductivity applied to this MgB₂ is applied to other intermetallics.

### EXAMPLE 1

### AlB₂-Type Intermetallic Sr₁₋ₓCaₓGa₂

Let us consider an intermetallic of the form Sr₁₋ₓCaₓGa₂ (0≦x≦1). We have that CaGa₂ and SrGa₂ can be formed in the AlB₂-type phase as shown in “L. H. Bennett and R. E. Watson, in Theory of Alloy Phase Formation, ed. L. H. Bennett, p. 425 (The Metallurgical Society AIME 1980)”. Thus the intermetallic Sr₁₋ₓCaₓGa₂ can also be formed in the AlB₂-type phase, with the unit cell as shown in FIG. 2 where the white balls representing Sr(Ca) (replacing Mg) and the black balls representing Ga (replacing B).

For the doping mechanism of superconductivity let us consider the following function:

f(x)=6491x₀+5500(1−x₀) (6)

where 6491 kJ/mol and 5500 kJ/mole are approximately the fourth ionization energies of Ca and Sr respectively. This function gives the relation that the increasing of x gives the increasing of h. Then we set the following relation of the degenerate state of channel opening:

f(x₀)=6491x₀+5500(1−x₀)=6200 (7)

for some x₀ (0≦x₀≦1) where 6200 kJ/mol is approximately the fourth ionization energy of Ga. A main point is that 6200 is close to 6491. When this relation holds (or approximately holds), the channel connecting the two states of fourth ionization energy of Ca and Ga can be opened. This channel opening gives a freedom of electric current with a direction orthogonal to the Ga plane. From this freedom of electric current, the Cooper pairs of the 3s, 3p-level electrons of Ga and Ca can be formed (In other words, through this channel opening the 3s, 3p-level electrons of Ga and Ca can transit from the valence band to the conduction band from which Cooper pairs of these electrons can be formed by the attractive electron-electron interaction from the seagull vertex term). Thus this channel opening gives the 3D region of conventional superconductivity. From this 3D conventional superconductivity we have the existence of quasi-2D bifurcation region of high-T_{c} superconductivity given by the Ga plane.

We notice that x₀≈0.706. Then Sr₁₋ₓCaₓGa₂ comes into the range of high-T_{c} superconductivity when x₀≦x≦x₁ for some x₁ such that 0<x₀<x₁≦1.

When (7) holds (or approximately holds) giving the channel opening, the 3s, 3p-level electrons of Ga in the Ga plane are in the basic state of fourth ionization energy and the 3s, 3p-level electrons of Ca are in the basic state of fourth ionization energy, and that other states are to be reached from these two states. Further the 3s, 3p-level electrons of Ga and Ca are unified to occupy a sequence of states such that the 3s, 3p-level electrons of Ga in the Ga plane occupy the higher states while the 3s, 3p-level electrons of Ca occupy the lower states.

Thus, as MgB₂, the 3s, 3p-level electrons of Ga are in the state of fifth ionization energy of Ga; and the 3s, 3p-level electrons of Ca are in the basic state of fourth ionization energy. The 3s, 3p-level electrons of Ca in the basic state of fourth ionization energy are in the opened channel of 3D superconductivity, while the 3s, 3p-level electrons of Ga in the state of fifth ionization energy are for the quasi-2D high-T_{c} superconductivity of the Ga plane.

Then when (7) holds (or approximately holds) giving the channel opening, the Cooper pairs of the s, p-valence electrons of Ga and Ca can also be formed. These s-valence electrons of Ga and Ca are in the basic state of first ionization energy.

Thus, the maximum value of the energy parameter |h_{Ga5}| of the 3s, 3p-level electrons of Ga is proportional to the fifth ionization energy of Ga; the maximum value of energy parameter |h_{Ca4}| of the 3s, 3p-level electrons of Ca is proportional to the fourth ionization energy of Sr; and the energy parameters |h_{Ga}| and |h_{Ca}| of the s-valence electrons of Ga and Ca are proportional to the first ionization energies of Ga and Ca respectively.

Then, from the state of superconductivity h²=3 κ², we have the following formula of T_{c} of Sr₁₋ₓCaₓGa₂:

$${k}_{B} {T}_{c} = κ = \frac{1}{\sqrt{3}} {Δ}_{CaSrGa} \qquad ( 8 )$$

where Δ_{CaSrGa}=h=24|h_{Ga5}|+4|h_{Ca4}|+6|h_{Ga}|+|h_{Ca}| is the energy gap of superconductivity of Sr₁₋ₓCaₓGa₂ where the coefficients 4, 6, 24=4·6 are from the

$$4 = \frac{8}{2}$$

for the eight 3s, 3p-level electrons of the Ga or Ca, and the 6 for the six Ga atoms of the hexagon of Ga. (For simplicity the effect of s-valence electrons of Sr and the effect of 3s, 3p-level electrons of Sr are omitted).

Then we have |h_{Ga}|≈ξ578.8 kJ/mol, |h_{Ga5}|=ξ8700 kJ/mol, |h_{Ca}|=ξ587.8 kJ/mol and |h_{Ca}|=ξ6491 kJ/mol; and 8700 kJ/mol is approximately the fifth ionization energy of Ga, and 578.8 kJ/mol, 587.8 kJ/mol are approximately the first ionization energies of Ga and Ca respectively. Then from (8) we can compute the highest critical temperature T_{c} of Sr₁₋ₓCaₓGa₂ which is upped to:

T_{c}≈463.9K (Computed T_{c} of Sr₁₋ₓCaₓGa₂) (9)

We may use other alkaline earth elements such as Ba (with fourth ionization energy≈4700 kJ/mol) to replace the alkaline earth element Sr (BaGa₂ can also be formed in the AlB₂-type phase). The highest critical temperature can also be upped to T_{c}≈463.9K.

From the property of the AlB₂-type superconductor A₁₋ₓ_{_{c}}Caₓ_{_{c}}Ga₂ (x_{c} is some doping value such that 0.1≦x_{c}≦0.99) where A=Sr, Ba, we give a process of manufacturing this superconductor, as follows. The powders of constituent of this superconductor A₁₋ₓ_{_{c}}Caₓ_{_{c}}Ga₂ are first mixed in accordance with the composition 0.1≦x_{c}≦0.9. Then the mixture of powders are melted in an induction furnace under argon atmosphere at a temperature between 700° C. and 1200° C. After the materials are melted, the melt is maintained at the same temperature for 20 minutes to 1 hour to achieve better homogeneity. The melt is then poured into a mold and under pressure between the ambient pressure and 6 GPa cooled down for solidification with AlB₂ phase. After cooling, the resulting ingot is annealed at a temperature between 300° C. and 900° C. in an argon atmosphere to achieve the state that the 3s, 3p-level electrons of Ga are in the degenerate state of channel opening. After cooling, this gives the superconductor A₁₋ₓ_{_{c}}Caₓ_{_{c}}Ga₂ in bulk form.

### EXAMPLE 2

### AlB₂-Type Intermetallic Sr₁₋ₓCaₓAlSi

Let us consider an intermetallic of the form Sr₁₋ₓCaₓAlSi (0.1≦x≦0.9). Under the ambient pressure CaAlSi and SrAlSi can be formed in the AlB₂-type as shown in “M. Imai, et al., Phys. Rev. Lett., 87, 077003 (2001)”. Thus Sr₁₋ₓCaₓAlSi can be formed in the AlB₂-type with Sr₁₋ₓCaₓ corresponding to Al and AlSi corresponding to B₂, with the unit cell as shown in FIG. 2 where the white balls representing Sr(Ca) (replacing Mg) and the black balls representing Si or Al (replacing B). Then each AlSi plane of Sr₁₋ₓCaₓAlSi consists of hexagons of three Al atoms and three Si atoms. We shall mainly consider the Si plane in a AiSi plane consisting of the Si atoms of the AlSi plane. For the doping mechanism of superconductivity let us consider the following function:

f(x)=4138(1−x)+4912.4x (10)

where 4138 kJ/mol and 4912.4 kJ/mole are approximately the third ionization energies of Sr and Ca respectively. This function gives the relation that the increasing of x gives the increasing of h. Then we set the following relation of the degenerate state of channel opening:

f(x₀)=4138(1−x₀)+4912.4x₀=4355.5 (11)

for some x₀ (0<x₀<1) where 4355.5 kJ/mol is approximately the fourth ionization energy of Si. A main point is that 4138 is close to 4355.5. When this relation holds (or approximately holds), the channel connecting the state of third ionization energy of Sr and the state of fourth ionization energy of Si can be opened.

This channel opening gives a freedom of electric current with a direction orthogonal to the Si plane. From this freedom of electric current, the Cooper pairs of s, p-valence electrons of Si and Sr, the 2s, 2p-level electrons of Si and 4s, 4p-level electrons of Sr can be formed. Thus this channel opening gives the 3D region of conventional superconductivity. From this 3D conventional superconductivity we have the existence of quasi-2D bifurcation region of high-T_{c} superconductivity given by the Si plane.

We notice that x₀≈0.28. Then Sr₁₋ₓCaₓAlSi comes into the range of superconductivity when x₀≦x≦x₁ for some x₁ such that x₀<x₁≦1.

When (11) holds (or approximately holds) giving channel opening, the s, p-valence electrons of Si in the Si plane are in the basic state of fourth ionization energy and the 4s, 4p-level electrons of Sr are in the basic state of third ionization energy, and that other states are to be reached from these two states. Further the s, p-valence and 2s, 2p-level electrons of Si in the Si plane and the 4s, 4p-level electrons of Sr are unified to occupy a sequence of states such that the 2s, 2p-level electrons of Si in the Si plane occupy the higher states while the 4s, 4p-level electrons of Sr occupy the lower states.

Thus, as MgB₂, the s, p-valence electrons of Si are in the basic state of fourth ionization energy of Si, the 2s, 2p-level electrons of Si are in the state of fifth ionization energy of Si; and the 4s, 4p-level electrons of Sr are in the basic state of third ionization energy. The s, p-valence electrons of Si in the basic state of fourth ionization energy and the 4s, 4p-level electrons of Sr in the basic state of third ionization energy are in the opened channel of 3D superconductivity, while the 2s, 2p-level electrons of Si in the state of fifth ionization energy are for the quasi-2D high-T_{c} superconductivity of the Si plane.

Thus, the maximum value of the energy parameter |h_{Si}| of the s, p-valence electrons of Si is proportional to the fourth ionization energy of Si, the maximum value of the energy parameter |h_{Si5}| of the 2s, 2p-level electrons of Si is proportional to the fifth ionization energy of Si; and the energy parameter |h_{Sr}| of the 4s, 4p-level electrons of Sr is proportional to the third ionization energy of Sr. Then, we have the following formula of T_{c} of Sr₁₋ₓCaₓAlSi:

$${k}_{B} {T}_{c} = κ = \frac{1}{\sqrt{3}} {Δ}_{SrCaAlSi} \qquad ( 12 )$$

where Δ_{SrCaAlSi}=h=6|h_{Si}|+12|h_{Si5}|+4|h_{Sr}| is the energy gap of superconductivity of Sr₁₋ₓCaₓAlSi where the coefficient 4 is from the

$$4 = \frac{8}{2}$$

for the eight 4s, 4p-level electrons of Sr; and the coefficients 12=4·3, 6=2·3 are from the

$$4 = \frac{8}{2}$$

for the eights 2s, 2p-level electrons of Si, the

$$2 = \frac{4}{2}$$

for the 3s, 3p-level electrons of Si, and the 3 for the three Si atoms of the hexagon consisting of Si and Al. (For simplicity the effect of Al, the effect of s, p-valence electrons of Sr and Ca, and the effect of s, p-nonvalence electrons of Ca are omitted).

We have |h_{Si}|≈ξ4355.5 kJ/mol, |h_{Si5}≈ξ16091 kJ/mol and |h_{Sr}|≈ξ4138 kJ/mol where 16091 kJ/mol is approximately the fifth ionization energy of Si. Then from (12) we can compute the highest critical temperature T_{c} of Sr₁₋ₓCaₓAlSi which is upped to:

T_{c}≈463.59K (Computed T_{c} of Sr₁₋ₓCaₓAlSi) (13)

For this AlB₂-type superconductor, we may use other alkaline earth elements such as Mg (with third ionization energy≈7732 kJ/mol) and Ba (with fourth ionization energy≈4700 kJ/mol) to replace Ca (with third ionization energy≈4912.4 kJ/mol).

It is known that under high pressure of about 16 GPa the intermetallics CaSi₂ and SrSi₂ are also of the AlB₂-type. Then similar to Sr₁₋ₓCaₓAlSi, the intermetallics Sr₁₋ₓCaₓSi₂ (0.1≦x≦0.9) is also a superconductor with the critical temperature T_{c}>300K for some doping value x_{c} of x, 0.1≦x_{c}≦9.

Since the first ionization energies of Ca and Sr are ≈589.7 kJ/mol and ≈549.5 kJ/mol which are close to the first ionization energies≈1577.5 kJ/mol of Al, there is a channel opening at first ionization energy states. This gives the superconductivity of CaAlSi and SrAlSi. For this superconductivity due to the channel opening of first ionization energy states, the computed T_{c} roughly agree with the experimental values≈7.8 kJ/mol and ≈5.1 kJ/mol of CaAlSi and SrAlSi.

From the property of the AlB₂-type superconductor Sr₁₋ₓ_{_{c}}Aₓ_{_{c}}AlSi (x_{c} is some doping value such that 0.1≦x_{c}≦0.9) where A=Ca, Ba, we have a process of manufacturing this superconductor, as follows. The powders of constituent of this superconductor Sr₁₋ₓ_{_{c}}Aₓ_{_{c}}AlSi are first mixed in accordance with the composition 0.1≦x_{c}≦0.9. Then the mixture of powders are melted in an induction furnace under argon atmosphere at a temperature between 300° C. and 1500° C. After the materials are melted, the melt is maintained at the same temperature for 20 minutes to 1 hour to achieve better homogeneity. The melt is then poured into a mold and under pressure between the ambient pressure and 6 GPa cooled down for solidification with AlB₂ phase. After cooling, the resulting ingot is annealed at a temperature between 300° C. and 1000° C. in an argon atmosphere to achieve the state that the 2s, 2p-level electrons of Si are in the degenerate state of channel opening. After cooling, this gives the superconductor Sr₁₋ₓ_{_{c}}Aₓ_{_{c}}AlSi in bulk form.

Since the AlB₂-type intermetallics Sr₁₋ₓAₓAlSi (0≦x≦1) are of the hexagonal crystal structure and contain the element Si, they are suitable as substrates for depositing thin films of superconductors of the hexagonal crystal structure.

### EXAMPLE 3

### AlB₂-Type Intermetallic La₁₋ₓBaₓCuGe

Let us consider an intermetallic La₁₋ₓBaₓCuGe (0≦x≦1). Under ambient pressure LaCuGe and BaCuGe can be formed in the AlB₂-type, as shown in “C. Zheng and R. Hoffmann, Inorg. Chem., 28, 1074 (1989)”. Thus La₁₋ₓBaₓCuGe can be formed in the AlB₂-type with La₁₋ₓBaₓ corresponding to Al and CuGe corresponding to B₂, with the unit cell as shown in FIG. 2 where the white balls representing La(Ba) (replacing Mg) and the black balls representing Cu or Ge (replacing B). Then each CuGe plane of La₁₋ₓBaₓCuGe consists of hexagons of three Cu atoms and three Ge atoms. Let us first consider the Cu plane in a CuGe plane consisting of the Cu atoms of the CuGe plane, then we consider the Ge plane in the same CuGe plane consisting of the Ge atoms of the CuGe plane. For the doping mechanism of superconductivity let us consider the following function:

f(x)=1850(1−x)+3600x (14)

where 3600 kJ/mol and 1850 kJ/mole are approximately the third ionization energy of Ba and La respectively. This function gives the relation that the increasing of x gives the increasing of h. Then we set the following relation of the degenerate state of channel opening:

f(x₀)=1850(1−x₀)+3600x₀=1957.9 (15)

for some x₀ (0≦x₀≦1) where 1957.9 kJ/mol is approximately the second ionization energy of Cu. When this relation holds (or approximately holds), the channel connecting the state of third ionization energy of La and the state of second ionization energy of Cu can be opened. This channel opening gives a freedom of electric current with a direction orthogonal to the Cu plane. From this freedom of electric current, the Cooper pairs of the 3d-level electrons of Cu can be formed. Thus this channel opening gives the 3D region of conventional superconductivity. From this 3D conventional superconductivity we have the existence of quasi-2D bifurcation region of high-T_{c} superconductivity given by the Cu plane. We notice that x₀≈0.062. Then La₁₋ₓBaₓCuGe comes into the range of superconductivity when x₀≦x≦x₁ for some x₁ such that x₀<x₁≦1.

When (15) holds (or approximately holds) giving channel opening, the 3d-level electrons of Cu in the Cu plane are in the basic state of second ionization energy and the 5d-level electron of La is in the basic state of third ionization energy, and that other states are to be reached from these two states. Further the 3d-level electrons of Cu in the Cu plane and the 5d-level electron of La are unified to occupy a sequence of states such that the 3d-level electrons of Cu in the Cu plane occupy the higher states while the 5d-level and s-valence electrons of La occupy the lower states. Thus, the 3d-level electrons of Cu are in the state of third ionization energy of Cu; 5d-level electrons of La in the basic state of third ionization energy of La, and the s-valence electrons of La are in the basic state of first (or second) ionization energy. We notice that the 5d-level electrons of La in the basic state of third ionization energy are in the opened channel of 3D superconductivity, while the 3d-level electrons of Cu in the state of third ionization energy are for the quasi-2D high-T_{c} superconductivity of the Cu plane. Thus, the maximum value of the energy parameter |h_{Cu3}| of the 3d-level electrons of Cu is proportional to the third ionization energy of Cu; and the energy parameter |h_{La}| of the s-valence electrons of La is proportional to the first (or second) ionization energy of La (There is no Cooper pair of 5d-level electrons of La since there is only one 5d-level electron of La).

Then let us consider the Ge plane in the same CuGe plane consisting of the Ge atoms of the CuGe plane. For the doping mechanism of superconductivity let us consider the following function:

g(x)=4410−4819(1−x) (16)

where 4410 kJ/mol and 4819 kJ/mole are approximately the fourth ionization energy of Ge and La respectively. This function gives the relation that the increasing of x gives the increasing of h. Then we set the following relation of the degenerate state of channel opening:

g(x′₀)=4410−4819(1−x′₀)=3600x′₀ (17)

for some x′₀ (0<x′₀<1) where 3600 kJ/mol is approximately the third ionization energy of Ba. When this relation holds (or approximately holds), the channel connecting the state of fourth ionization energy of La and the state of fourth ionization energy of Ge can be opened. This channel opening gives a freedom of electric current with a direction orthogonal to the Ge plane. From this freedom of electric current, the Cooper pairs of the 3s, 3p-level electrons of Ge, the 4s, 4p-level electrons of Ge and 5s, 5p-level electrons of La can be formed. Thus this channel opening gives the 3D region of conventional superconductivity. From this 3D conventional superconductivity we have the existence of quasi-2D bifurcation region of high-T_{c} superconductivity given by the Ge plane. We notice that x′₀≈0.335. Then La₁₋ₓBaₓCuGe comes into the range of superconductivity when x′₀≦x≦x₁ for some x₁ such that x═₀<x₁≦1.

Thus for both the Cu and Ge atoms, when x′₀≈0.335, La₁₋ₓBaₓCuGe comes into the range of superconductivity when x′₀≦x≦x₁ for some x₁ such that x′₀<x₁≦1.

When (17) holds (or approximately holds) giving channel opening, the 4s, 4p-level electrons of Ge in the Ge plane are in the basic state of fourth ionization energy and the 5s, 5p-level electrons of La are in the basic state of fourth ionization energy, and that other states are to be reached from these two states. Further the 4s, 4p-level and 3s, 3p-level electrons of Ge in the Ge plane and the 5s, 5p-level electrons of La are unified to occupy a sequence of states such that the 3s, 3p-level electrons of Ge in the Ge plane occupy the higher states while the 5s, 5p-level and 6s-level electrons of La occupy the lower states. Thus, the 4s, 4p-level electrons of Ge are in the basic state of fourth ionization energy of Ge, the 3s, 3p-level electrons of Ge are in the state of fifth ionization energy of Ge; and the 5s, 5p-level electrons of La are in the basic state of fourth ionization energy.

We notice that the 4s, 4p-level electrons of Ge in the basic state of fourth ionization energy are in the opened channel of 3D superconductivity, while the 3s, 3p-level electrons of Ge in the state of fifth ionization energy are for the quasi-2D high-T_{c} superconductivity of the Ge plane. Thus, the maximum value of the energy parameter |h_{Ge}| of the 4s, 4p-level electrons of Ge is proportional to the fourth ionization energy of Ge, the maximum value of the energy parameter |h_{Ge5}| of the 3s, 3p-level electrons of Ge is proportional to the fifth ionization energy of Ge; and the energy parameter |h_{La4}| of the 5s, 5p-level electrons of La is proportional to the fourth ionization energy of La. Then, we have the following formula of T_{c} of La₁₋ₓBaₓCuGe:

$${k}_{B} {T}_{c} = κ = \frac{1}{\sqrt{3}} {Δ}_{LaBaCuGe} \qquad ( 18 )$$

where Δ_{LaBaCuGe}=h=(4|h_{La4}|+12|h_{Ge5}|+6|h_{Ge}|)+(15|h_{Cu3}|+|h_{La}|) is the energy gap of superconductivity of La₁₋ₓBaₓCuGe where the coefficient 4 is from the

$$4 = \frac{8}{2}$$

for the eight 5s, 5p-level electrons of La; and the coefficients 12=4·3, 6=2·3 and 15=5·3 are from the

$$4 = \frac{8}{2}$$

for the eight, 3s, 3p-level electrons of Ge, the

$$2 = \frac{4}{2}$$

for the 4s, 4p-level electrons of Ge, the

$$5 = \frac{10}{2}$$

for the ten 3d-level electrons of Cu, and the 3 for the three Ge atoms and three Cu atoms of the hexagon consisting of Ge and Cu.

We have |h_{Ge}|≈ξ4410 kJ/mol, |h_{Ge5}|≈ξ9020 kJ/mol and |h_{La4}|≈ξ4819 kJ/mol, |h_{Cu3}≈ξ3555 kJ/mol, |h_{La}|≈ξ1067 kJ/mol, where 9020 kJ/mol is approximately the fifth ionization energy of Ge and 1067 kJ/mol is approximately the second ionization energy of La. Then from (18) we can compute the highest critical temperature T_{c} which is upped to:

T_{c}≈409.70K (Computed T_{c} of La₁₋ₓBaₓCuGe) (19)

For this AlB₂-type superconductor, we may use other alkaline earth elements such as Sr (with third ionization energy≈4210 kJ/mol) and Ca (with second ionization energy≈1145 kJ/mol and third ionization energy≈4910 kJ/mol) to replace Ba (with third ionization energy≈3600 kJ/mol). Also we may use Si (with fourth ionization energy≈4355.5 kJ/mol) to replace Ge (with fourth ionization energy≈4410 kJ/mol). Since the fourth ionization energy of Si is not as close to that of La as the fourth ionization energy of Ge, it may be more difficult to have the channel opening for this Si-substitution. We may also synthesize AlB₂-type intermetallic of the form La_{(1-x)(1-y)}Ce_{y}BaₓCuGe (0≦y≦1) or Mm₁₋ₓBaₓCuGe where Mm denotes the Mischmetal. Also we may use other mixtures of rare earth elements to replace La.

### EXAMPLE 4

### AlB₂-Type Intermetallic Gd₁₋ₓCaₓCuSi

Let us consider an intermetallic Gd₁₋ₓCaₓCuSi (0≦x≦1). Under ambient pressure GdCuSi and CaCuSi can be formed in the AlB₂-type. Thus Gd₁₋ₓCaₓCuSi can be formed in the AlB₂-type with Gd₁₋ₓCaₓ corresponding to Al and CuSi corresponding to B₂, with the unit cell as shown in FIG. 2 where the white balls representing the elements Gd(Ca) (replacing Mg) and the black balls representing the elements Cu or Si (replacing B). Then each CuSi plane of Gd₁₋ₓCaₓCuSi consists of hexagons of three Cu atoms and three Si atoms.

Let us first consider the Cu plane in a CuSi plane consisting of the Cu atoms of the CuSi plane, then we consider the Si plane in the same CuSi plane consisting of the Si atoms of the CuSi plane. For the doping mechanism of superconductivity let us consider the following function:

f(x)=1957.9−1990(1−x) (20)

where 1957.9 kJ/mol and 1990 kJ/mole are approximately the second ionization energy of Cu and the third ionization energy of Gd respectively. This function gives the relation that the increasing of x gives the increasing of h. Then we set the following relation of the degenerate state of channel opening:

f(x₀)=1957.9−1990(1−x₀)=1145x₀ (21)

for some x₀ (0<x₀<1) where 1145 kJ/mol is approximately the second ionization energy of Ca. When this relation holds (or approximately holds), the channel connecting the state of third ionization energy of Gd and the state of second ionization energy of Cu can be opened. This channel opening gives a freedom of electric current with a direction orthogonal to the Cu plane. From this freedom of electric current, the Cooper pairs of the 3d-level electrons of Cu can be formed. Thus this channel opening gives the 3D region of conventional superconductivity. From this 3D conventional superconductivity we have the existence of quasi-2D bifurcation region of high-T_{c} superconductivity given by the Cu plane. We notice that x₀≈0.038. Then Gd₁₋ₓCaₓCuSi comes into the range of superconductivity when x₀≦x≦x₁ for some x₁ such that x₀<x₁≦1.

When (21) holds (or approximately holds) giving channel opening, the 3d-level electrons of Cu in the Cu plane are in the basic state of second ionization energy and the 5d-level electrons of Gd are in the basic state of third ionization energy, and that other states are to be reached from these two states. Further the 3d-level electrons of Cu in the Cu plane and the 5d-level electrons of Gd are unified to occupy a sequence of states such that the 3d-level electrons of Cu in the Cu plane occupy the higher states while the 5d-level electrons of Gd occupy the lower states. Thus, the 3d-level electrons of Cu are in the state of third ionization energy of Cu; the 5d-level electrons of Gd in the basic state of third ionization energy of Gd, and the s-valence electrons of Gd are in the basic state of first (or second) ionization energy.

We notice that the 5d-level electrons of Gd in the basic state of third ionization energy are in the opened channel of 3D superconductivity, while the 3d-level electrons of Cu in the state of third ionization energy are for the quasi-2D high-T_{c} superconductivity of the Cu plane. Thus, the maximum value of the energy parameter |h_{cu3}| of the 3d-level electrons of Cu is proportional to the third ionization energy of Cu; and the energy parameter |h_{Gd}| of the s-valence electrons of Gd is proportional to the first (or second) ionization energy of Gd (There is no Cooper pair of 5d-level electrons of Gd since there is only one 5d-level electron of Gd).

Then let us consider the Si plane in the same CuSi plane consisting of the Si atoms of the CuSi plane. For the doping mechanism of superconductivity let us consider the following function:

g(x)=4250(1−x)+4910x (22)

where 4250 kJ/mol and 4910 kJ/mole are approximately the fourth ionization energy of Gd and the third ionization energy of Ca respectively. This function gives the relation that the increasing of x gives the increasing of h. Then we set the following relation of the degenerate state of channel opening:

g(x′₀)=4250(1−x═₀)+4910x′₀=4355.5 (23)

for some x′₀ (0<x′₀<1) where 4355.5 kJ/mol is approximately the fourth ionization energy of Si. When this relation holds (or approximately holds), the channel connecting the state of fourth ionization energy of Gd and the state of fourth ionization energy of Si can be opened. This channel opening gives a freedom of electric current with a direction orthogonal to the Si plane. From this freedom of electric current, the Cooper pairs of the 2s, 2p-level electrons of Si and 5s, 5p-level electrons of Gd can be formed. Thus this channel opening gives the 3D region of conventional superconductivity. From this 3D conventional superconductivity we have the existence of quasi-2D bifurcation region of high-T_{c} superconductivity given by the Si plane. We notice that x′₀≈0.16. Then Gd₁₋ₓCaₓCuSi comes into the range of superconductivity when x′₀≦x≦x₁ for some x₁ such that x′₀<x₁≦1.

Thus for both the Cu and Si atoms, when x′₀≈0.16, Gd₁₋ₓCaₓCuSi comes into the range of superconductivity when x′₀≦x≦x₁ for some x₁ such that x′₀<x₁≦1.

When (23) holds (or approximately holds) giving channel opening, the 3s, 3p-level electrons of Si in the Si plane are in the basic state of fourth ionization energy and the 5s, 5p-level electrons of Gd are in the basic state of fourth ionization energy, and that other states are to be reached from these two states. Further the 3s, 3p-level and 2s, 2p-level electrons of Si in the Si plane and the 5s, 5p-level electrons of Gd are unified to occupy a sequence of states such that the 2s, 2p-level electrons of Si in the Si plane occupy the higher states while the 5s, 5p-level and 6s-level electrons of Gd occupy the lower states. Thus, the 3s, 3p-level electrons of Si are in the basic state of fourth ionization energy of Si, the 2s, 2p-level electrons of Si are in the state of fifth ionization energy of Si; and the 5s, 5p-level electrons of Gd are in the basic state of fourth ionization energy.

We notice that the 3s, 3p-level electrons of Si in the basic state of fourth ionization energy are in the opened channel of 3D superconductivity, while the 2s, 2p-level electrons of Si in the state of fifth ionization energy are for the quasi-2D high-T_{c} superconductivity of the Si plane. Thus, the maximum value of the energy parameter |h_{Si}| of the 3s, 3p-level electrons of Si is proportional to the fourth ionization energy of Si, the maximum value of the energy parameter |h_{Si5}| of the 2s, 2p-level electrons of Si is proportional to the fifth ionization energy of Si; the energy parameter |h_{Gd}| of the 5s, 5p-level electrons of Gd is proportional to the fourth ionization energy of Gd, and the energy parameter |h_{Gd}| of the s-valence electrons of Gd is proportional to the first (or second) ionization energy of Gd. Then, we have the following formula of T_{c} of Gd₁₋ₓCaₓCuSi:

$${k}_{B} {T}_{c} = κ = \frac{1}{\sqrt{3}} {Δ}_{GdCaCuSi} \qquad ( 24 )$$

where Δ_{GdCaCuSi}=h=(4|h_{Gd4}|+12|h_{Si5}|+6|h_{Si}|)+(15|h_{Cu3}|+|h_{Gd}|) is the energy gap of superconductivity of Gd₁₋ₓCaₓCuSi where the coefficient 4 is from the

$$4 = \frac{8}{2}$$

for the eight 5s, 5p-level electrons of Gd; and the coefficients 12=4·3, 6=2·3 and 15=5·3 are from the

$$4 = \frac{8}{2}$$

for the eight 2s, 2p-level electrons of Si, the

$$2 = \frac{4}{2}$$

for the 3s, 3p-level electrons of Si, the

$$5 = \frac{10}{2}$$

for the ten 3d-level electrons of Cu, and the 3 for the three Si atoms and three Cu atoms of the hexagon consisting of Si and Cu.

We have |h_{Si}″≈ξ4355.51 kJ/mol, |h_{Si5}|≈ξ16091 kJ/mol and |h_{Gd4}|≈ξ4250 kJ/mol, |h_{Cu3}|≈ξ3555 kJ/mol, |h_{Gd}|≈ξ1167 kJ/mol where 16091 kJ/mol is approximately the fifth ionization energy of Si and 1167 kJ/mol is approximately the second ionization energy of Gd. Then from (24) we can compute the highest critical temperature T_{c} which is upped to:

T_{c}≈571.62K (Computed of Gd₁₋ₓCaₓCuSi) (25)

For this AlB₂-type superconductor, we may use other alkaline earth elements such as Sr and Ba to replace Ca. Also we may use Ge to replace Si. We may further use rare earth elements and the mixture thereof to replace Gd. A main point for these generalizations is the forming of the degenerate state of channel opening for the superconductivity in these generalizations.

From the property of the AlB₂-type superconductor R₁₋ₓ_{_{c}}Aₓ_{_{c}}CuG (x_{c} is some doping value such that 0.25≦x_{c}≦0.8) where R═La, Gd or rare earth metals and mixture thereof, A=Ca, Sr, Ba, G=Si, Ge, we have a process of manufacturing this superconductor, as follows. The powders of constituent of this superconductor R₁₋ₓ_{_{c}}Aₓ_{_{c}}CuG are first mixed in accordance with the composition 0.25≦x_{c}≦0.8. Then the mixture of powders are melted in an induction furnace under argon atmosphere at a temperature between 1000° C. and 1500° C. After the materials are melted, the melt is maintained at the same temperature for 20 minutes to 1 hour to achieve better homogeneity. The melt is then poured into a mold and under pressure between the ambient pressure and 6 GPa cooled down for solidification with AlB₂ phase. After cooling, the resulting ingot is annealed in a furnace at a temperature between 500° C. and 1000° C. in an argon atmosphere to achieve the state that the d-level electrons of Cu and 3s, 3p-level electrons of Si (or 4s, 4p-level electrons of Ge) are in the degenerate state of channel opening. After cooling, this gives the superconductor R₁₋ₓ_{_{c}}Aₓ_{_{c}}CuG in bulk form.

### EXAMPLE 5

### CaCu₅-Type Intermetallic La₁₋ₓCaₓCu₅

Let us consider an intermetallic La₁₋ₓCaₓCu₅ (0≦x≦1). We have that the intermetallics LaCu₅ and CaCu₅ are of the CaCu₅-type as shown in “D. J. Chakrabari and D. E. Laughlin, Bull. Alloy Phase Diagram, 2, 319 (1981)” and “P. R. Subramanian and D. E. Laughlin, Bull. Alloy Phase Diagram, 9, 316 (1988)”. Thus the crystal structure of La₁₋ₓCaₓCu₅ can be formed in the CaCu₅-type with La₁₋ₓCaₓ corresponding to Ca.

This CaCu₅-type is similar to the AlB₂-type with the hexagon of six B atoms replaced by an enlarged hexagon of twelve Cu atoms and a hexagon of six Cu atoms is intercalated in one of the two Ca planes which replaces the corresponding one of the two Al planes of AlB₂. There are eighteen Cu atoms near the faces of a unit cell of the hexagonal structure of CaCu₅ (where twelve Cu atoms are from the two hexagons of six Cu atoms intercalated in the two Ca planes and six Cu atoms are from the enlarged hexagon of Cu). FIG. 3 shows the crystal structure of two of the three layers of a unit cell of La₁₋ₓCaₓCu₅ of CaCu₅-type. Thus in a unit cell of CaCu₅ nine Cu atoms of the twelve Cu atoms of the enlarged hexagon of Cu and six Cu atoms of the two hexagons of Cu and one face-centered Ca atom are as a cluster of atoms. For the doping mechanism of superconductivity let us consider the following function:

f(x)=1850(1−x)+4912.4x (26)

where 1850 kJ/mol and 4912.4 kJ/mole are approximately the third ionization energies of La and Ca respectively. This function gives the relation that the increasing of x gives the increasing of h. Then we set the following relation of the degenerate state of channel opening:

f(x₀)=1850(1−x₀)+4912.4x₀=1957.9 (27)

for some x₀ (0<x₀<1) where 1957.9 kJ/mol is approximately the second ionization energy of Cu. When this relation holds (or approximately holds), the channel connecting the state of third ionization energy of La and the state of second ionization energy of Cu can be opened. This channel opening gives a freedom of electric current with a direction orthogonal to the Cu plane. By this freedom of electric current, the valence electrons of a cluster of atoms in a unit cell can be coupled to the valence electrons of other clusters to form Cooper pairs. In this way the Cooper pairs of d-valence electrons of Cu and the Cooper pair of the s-valence electrons of La can be formed (In other words, through this channel opening the d-valence electrons of Cu can transit from the valence band to the conduction band from which Cooper pairs of these d-valence electrons can be formed by the attractive electron-electron interaction from the seagull vertex term). Thus this channel opening together with the Cu plane gives the region of 3D conventional superconductivity. From this region of 3D superconductivity we have the existence of quasi-2D bifurcation region of the high-T_{c} superconductivity given by the Cu plane. We notice that x₀≈0.035. Then La₁₋ₓCaₓCu₅ comes into the range of superconductivity when x₀<x<x₁ for some x₁ such that x₀<x₁<1. When (27) holds (or approximately holds) giving channel opening, the d-valence electrons of Cu in the Cu plane are in the basic state of second ionization energy and the d-valence electron of La is in the basic state of third ionization energy, and that other states are to be reached from these two states. Further the d-valence electrons of Cu in the Cu plane and the d-valence electron of La are unified to occupy a sequence of states such that the d-valence electron of Cu in the Cu plane occupy the higher states while the d-valence electron of La occupy the lower state: Thus, as MgB₂, the d-valence electrons of Cu are in the basic state of third ionization energy, the d-valence electron of La is in the state of third ionization energy; and the s-valence electrons of La is in the basic state of first ionization energy.

Thus, the maximum value of the energy parameter |h_{Cu}| of the d-valence electrons of Cu is proportional to the third ionization energy of Cu, and the energy parameter |h_{La}| of the s-valence electrons of La is proportional to the first ionization energy of La. Then, from the state of superconductivity h²=3 κ², if we omit the effect of the hexagon of six Cu atoms intercalated in the La plane, we have the following formula of T_{c} of La₁₋ₓCaₓCu₅:

$${k}_{ B} {T}_{c} = κ = \frac{1}{\sqrt{3}} {Δ}_{LaCaCu} \qquad ( 28 )$$

where Δ_{LaCaCu}=h=45|h_{Cu}|+|h_{La}| is the energy gap of the superconductivity of La₁₋ₓCaₓCu₅ where the coefficient 45=5·9 are from the

$$5 = \frac{10}{2}$$

for the ten d-valence electrons of the Cu, and the 9 for the nine Cu atoms in the enlarged hexagon of Cu. (For simplicity the effect of s, d-valence electrons of Ca is omitted). We have |h_{Cu}|≈ξ3555 kJ/mol, and |h_{La}|≈ξ538.1 kJ/mol where 3555 kJ/mol is approximately the third ionization energy of Cu and 538.1 kJ/mol is approximately the first ionization energy of La. Then from (28) we can compute the highest critical temperature T_{c} of La₁₋ₓCaₓCu₅ which is upped to:

T_{c}≈315.6K (Computed T_{c} of La₁₋ₓCaₓCu₅) (29)

If we include the effect of the hexagon of six Cu atoms intercalated in the La plane and suppose that this effect is the same as the enlarged hexagon of twelve Cu atoms. Then the term 45|h_{Cu}| in Δ_{LaCaCu} becomes 75|h_{Cu}|. Then the highest critical temperature T_{c} of La₁₋ₓCaₓCu₅ is upped to:

T_{c}≈525.3K (Computed T_{c} of La₁₋ₓCaₓCu₅) (30)

We may use other alkaline earth elements such as Sr (with the third ionization energy≈4138 kJ/mol) to replace Ca to form the intermetallic La₁₋ₓSrₓCu₅ (SrCu₅ is also of the CaCu₅-type). The doping mechanism is similar to La₁₋ₓCaₓCu₅ with x₀≈0.047. The highest critical temperature can be upped to T_{c}≈525.3K. We have that La₁₋ₓSrₓCu₅ is easier to be synthesized than La₁₋ₓCaₓCu₅ since 4138<4912.4. Further, we may use a mixture of Ca and Sr, denoted by A, to replace Ca to form the intermetallic La₁₋ₓAₓCu₅ (0≦x≦1). Also we may use a mixture of Cu and Zn to replace Cu to form the intermetallic La₁₋ₓAₓCu₅(1−y)Zn_{5y} (0≦y≦1). Also we may use rare earth elements R (or mixture thereof) with the third ionization energy>1957.9 kJ/mol to replace Ca to form the intermetallic La₁₋ₓRₓCu₅.

### EXAMPLE 6

### CaCu₅-Type Intermetallic GdₓCa₁₋ₓCu₅

Let us use other rare earth elements such as Gd to replace the element La to form the intermetallic GdₓCa₁₋ₓCu₅ (0≦x≦1) (GdCu₅ is also of the CaCu₅-type). For the doping mechanism let us consider the following function:

f(x)=1957.9−1145.4(1−x) (31)

where 1957.9 kJ/mol and 1145.4 kJ/mole are approximately the second ionization energies of Cu and Ca respectively. This function gives the relation that the increasing of x gives the increasing of h. Then we set the following relation of the degenerate state of channel opening:

f(x₀)=1957.9−1145.4(1−x₀)=1990x₀ (32)

for some x₀ (0<x₀<1) where 1990 kJ/mol is approximately the third ionization energy of Gd. Then we have x₀≈0.96. Then GdₓCa₁₋ₓCu₅ comes into the range of superconductivity when x₂≦x≦x₀ for some x₂ such that 0≦x₂<x₀<1. Then, as La₁₋ₓCaₓCu₅, we have the following formula of T_{c} of GdₓCa₁₋ₓCu₅:

$${k}_{B} {T}_{c} = κ = \frac{1}{\sqrt{3}} {Δ}_{GdCaCu} \qquad ( 33 )$$

where Δ_{GdCaCu}=h=75|h_{Cu}|+|h_{Gd}| is the energy gap of the superconductivity of GdₓCa₁₋ₓCu₅, |h_{Cu}|≈ξ3555 kJ/mol, and |h_{Gd}|≈ξ592.5 kJ/mol where 592.5 kJ/mol is approximately the first ionization energy of Gd. Then from (33) we can compute the highest critical temperature T_{c} of GdₓCa₁₋ₓCu₅ which is upped to:

T_{c}≈525.4K (Computed T_{c} of GdₓCa₁₋ₓCu₅) (34)

We may use other alkaline earth elements such as Sr (with the second ionization energy≈1064.2 kJ/mol) to replace Ca to form the intermetallic GdₓSr₁₋ₓCu₅ (0≦x≦1). The doping mechanism is similar to GdₓCa₁₋ₓCu₅ with x₀≈0.96. The highest critical temperature is upped to T_{c}≈525.4K.

### EXAMPLE 7

### CaCu₅-Type Intermetallic YₓCa₁₋ₓCu₅

We may also use other rare earth elements such as Y to replace the element La to form the intermetallic YₓCa₁₋ₓCu₅ (0≦x≦1) (YCu₅ is also of the CaCu₅-type). For the doping mechanism we consider the following function:

f(x)=1957.9−1145.4(1−x) (35)

where 1957.9 kJ/mol and 1145.4 kJ/mole are approximately the second ionization energies of Cu and Ca respectively. This function gives the relation that the increasing of x gives the increasing of h. Then we set the following relation of the degenerate state of channel opening:

f(x₀)=1957.9−1145.4(1−x₀)=1980x₀ (36)

for some x₀ (0<x₀<1) where 1980 kJ/mol is approximately the third ionization energy of Y. Then we have x₀≈0.96. Then YₓCa₁₋ₓCu₅ comes into the range of superconductivity when x₂≦x’x₀ for some x₂ such that 0≦x₂≦x₀<1. Then, similar to La₁₋ₓCaₓCu₅, we have the following formula of T_{c} of YₓCa₁₋ₓCu₅:

$${k}_{B} {T}_{c} = κ = \frac{1}{\sqrt{3}} {Δ}_{Y CaCu} \qquad ( 37 )$$

where Δ_{YCaCu}=h=75|h_{Cu}|+|h_{Y}| is the energy gap of the superconductivity of YₓCa₁₋ₓCu₅, |h_{Cu}|≈ξ3555 kJ/mol, and |h_{y}|≈ξ600 kJ/mol where 600 kJ/mol is approximately the first ionization energy of Y. Then from (37) we can compute the highest critical temperature T_{c} of YₓCa₁₋ₓCu₅ which is upped to:

T_{c}≈525.43K (Computed T_{c} of YₓCa₁₋ₓCu₅) (38)

We may use other alkaline earth elements such as Sr to replace Ca to form the intermetallic YₓSr₁₋ₓCu₅ (0≦x≦1). The doping mechanism is similar to YₓCa₁₋ₓCu₅ with x₀≈0.96. The highest critical temperature is upped to T_{c}≈525.43K.

### EXAMPLE 8

### CaCu₅-Type Intermetallic LaNi₅₋₅ₓCu₅ₓ

Let us consider an intermetallic LaNi₅₍₁₋ₓ₎Cu₅ₓ (0≦x≦1). We have that the intermetallics LaCu₅ and LaNi₅ are of the CaCu₅-type. Thus LaNi₅₍₁₋ₓ₎Cu₅ₓ can be formed in the CaCu₅-type with Ca corresponding to La and Cu corresponding to Ni₍₁₋ₓ₎Cuₓ. For the doping mechanism of superconductivity let us consider the following function:

f(x)=1753(1−x)+1957.9x (39)

where 1753 kJ/mol and 1957.9 kJ/mole are approximately the second ionization energies of Ni and Cu respectively. This function gives the relation that the increasing of x gives the increasing of h. Then we set the following relation of the degenerate state of channel opening:

f(x₀)=1753(1−x₀)+1957.9x₀=1850 (40)

for some x₀ (0<x₀<1) where 1850 kJ/mol is approximately the third ionization energy of La. When this relation holds (or approximately holds), the channel connecting the state of third ionization energy of La and the state of second ionization energy of Ni(Cu) can be opened. In this case of channel opening the Cooper pairs of d-valence electrons of Ni(Cu), the Cooper pairs of s-valence electrons of La, and the bifurcation region of high-T_{c} superconductivity can be formed. We notice that x₀≈0.4734. Then LaNi₅₍₁₋ₓ₎Cu₅ₓ comes into the range of superconductivity when x₀≦x≦x₁ for some x₁ such that x_{0<}x₁<1.

For this intermetallic LaNi₅₍₁₋ₓ₎Cu₅ₓ we have another doping mechanism of superconductivity. Let us consider the following function:

g(x)=1753(1−x)+3555x (41)

where 3555 kJ/mole is approximately the third ionization energy of Cu. This function also gives the relation that the increasing of x gives the increasing of h. Then we set the following relation of the degenerate state of channel opening:

g(x′₀)=1753(1−x′₀)+3555x′₀=1850 (42)

for some x′₀ (0<x′₀<1) where 1850 kJ/mol is again approximately the third ionization energy of La (The ionization energy of Cu can be the second or the third ionization energies). When this relation holds (or approximately holds) we also have that the channel connecting the state of third ionization energy of La and the state of second ionization energy of Ni(Cu) can be opened. Then we have x′₀≈0.0538. Then LaNi₅₍₁₋ₓ₎Cu₅ₓ comes into the range of superconductivity when x′₀≦x≦x₁ for some x₁ such that x′₀<x₁≦1. We notice that x′₀ is more close to 0 than x₀. Since x′₀≈0, we have that LaNi₅ can be formed in the degenerate state of channel opening. Thus LaNi₅ can be formed as a superconductor. When (40) holds (or when (42) holds) giving channel opening, the d-valence electrons of Ni in the Ni(Cu) plane are in the basic state of second ionization energy and the d-valence electrons of La are in the basic state of third ionization energy, and that other states are to be reached from these two states. Further the d-valence electrons of Ni in the Ni(Cu) plane and the d-valence electron of La are unified to occupy a sequence of states such that the d-valence electrons of Ni in the Ni(Cu) plane occupy the higher states while the d-valence electron of La occupies the lower state. Thus, as MgB₂, the d-valence electrons of Ni are in the state of third ionization energy, the d-valence electron of La is in the state of third ionization energy; and the s-valence electrons of Ni are in the state of first ionization energy, the s-valence electrons of La are in the state of first ionization energy. Thus, the maximum value of the energy parameter |h_{Ni}| of the d-valence electrons of Ni is proportional to the third ionization energy≈3395 kJ/mol of Ni, the energy parameter |h_{Ni1}| of the s-valence electrons of Ni is proportional to the first ionization energy≈737.1 kJ/mol of Ni, and the energy parameter |h_{La}| of the s-valence electrons of La is proportional to the first ionization energy of La. Then, as La₁₋ₓCaₓCu₅, we have the following formula of T_{c} of LaNi₅₍₁₋ₓ₎Cu₅ₓ:

$${k}_{B} {T}_{c} = κ = \frac{1}{\sqrt{3}} {Δ}_{LaNiCu} \qquad ( 43 )$$

where Δ_{LaNiCu}=h=60|h_{Ni}|+15|h_{Ni1}|+|h_{La}| is the energy gap of LaNi₅₍₁₋ₓ₎Cu₅ₓ and 60=4·15 where

$$4 = \frac{8}{2}$$

is from the 8 d-valence electrons of Ni, and the 15 for the fifteen Ni(Cu) atoms of the cluster of Ni(Cu) atoms in a unit cell (For simplicity the effect of d-valence electrons of Cu is omitted). Then from (43) we can compute the critical temperature T_{c} of LaNi₅₍₁₋ₓ₎Cu₅ₓ which is upped to:

T_{c}≈423.321K (Computed T_{c} of LaNi₅₍₁₋ₓ₎Cu₅ₓ) (44)

We may use other transition elements such as Co to replace Ni or Cu of LaNi₅₍₁₋ₓ₎Cu₅ₓ.

Since x′₀≈0, we have that LaNi₅ can be formed in the degenerate state of channel opening and thus LaNi₅ can be formed as a superconductor with T_{c} upped to 423.321K. This intermetallic LaNi₅ had been used for hydrogen storage since LaNi₅ is easy to be activated and can store a large amount of hydrogen under ambient pressure and in the room temperature. Since the activation and the hydrogen storage of a material is from the activity of electrons of this material, this property of LaNi₅ shows that the d-valence electrons of Nᵢ and La in LaNi₅ is in the degenerate state of channel opening.

### EXAMPLE 9

### CaCu₅-Type Intermetallic La₁₋ₓCeₓNi_{5-5c}Cu_{5c}

Let us consider an intermetallic La₁₋ₓCeₓNi_{5(1-c)}Cu_{5c} (0≦x, c≦1). This intermetallic can also be of the CaCu₅-type. For the doping mechanism let us consider the following function:

f(x)=1850(1−x)+1949x (45)

where 1850 kJ/mol and 1949 kJ/mole are approximately the third ionization energies of La and Ce respectively. This function gives the relation that the increasing of x gives the increasing of h. Then we set the following relation of the degenerate state of channel opening:

f(x₀)=1850(1−x₀)+1949x₀=1753(1−c)+1957.9c (46)

for some x₀ (0<x₀<1) and some c>0. When this relation holds (or approximately holds), the channel connecting the state of third ionization energy of La(Ce) and the state of second ionization energy of Cu(Ni) can be opened. In this case of channel opening the Cooper pairs of d-valence electrons of Cu(Ni) and the bifurcation region of high-T_{c} superconductivity can be formed. When

$$c < \frac{1}{2} ,$$

this intermetallic La₁₋ₓCeₓNi₅₍₁₋ₓ₎Cu_{5c} is similar to LaNi₅₍₁₋ₓ₎Cu₅ₓ with Ni as the main part and we omit the details. When

$$c > \frac{1}{2} ,$$

then Cu is as the main part. Thus, as La₁₋ₓCaₓCu₅, when c is close to 1 we have the following formula (with approximation) of Tₓ of La₁₋ₓCeₓNi_{5(1-c)}Cu_{5c}:

$${k}_{B} {T}_{c} = κ = \frac{1}{\sqrt{3}} {Δ}_{LaCeNiCu} \qquad ( 47 )$$

where Δ_{LaCeNiCu}=h=75|h_{Cu}|+|h_{La}| is the energy gap of La₁₋ₓCeₓNi_{5(1-c)}Cu_{5c}. (For simplicity the effect of s, d, f-valence electrons of Ni and Ce is omitted). Then from (47) we can compute the critical temperature T_{c} of La₁₋ₓCeₓNi_{5(1-c)}Cu_{5c} which is upped to:

T_{c}≈525.3K (Computed T_{c} of La₁₋ₓCeₓNi_{5(1-c)}Cu_{5c}) (48)

We may replace Ce with a mixture of rare earth elements. When

$${x}_{0} \geq \frac{2}{5}$$

this family of CaCu₅-type superconductors includes the intermetallic MmNi_{5(1-c)}Cu_{5c} where Mm denotes a Mischmetal which is a mixture of rare earth elements with the fractional part of Ce more than ⅖. In particular we have the intermetallic MmNi₅. Then as LaNi₅ we have that MmNi₅ is a superconductor with T_{c}>300K.

### EXAMPLE 10

### CaCu₅-Type Intermetallic YNi₅₍₁₋ₓ₎Cu₅ₓ

Let us consider an intermetallic YNi₅₍₁₋ₓ₎Cu₅ₓ (0≦x≦1). We have that the intermetallics YCu₅ and YNi₅ are of the CaCu₅-type. Thus YNi₅₍₁₋ₓ₎Cu₅ₓ can be formed in the CaCu₅-type with Ca corresponding to Y and Cu corresponding to Ni₍₁₋ₓ₎Cuₓ. For the doping mechanism of superconductivity let us consider the following function:

f(x)=1980−3393(1−x) (49)

where 1980 kJ/mol and 3393 kJ/mole are approximately the third ionization energies of Y and Ni respectively. This function gives the relation that the increasing of x gives the increasing of h. Then we set the following relation of the degenerate state of channel opening:

f(x₀)=1980−3393(1−x₀)=1957.9x₀ (50)

for some x₀ (0<x₀<1) where 1957.9 kJ/mol is approximately the second ionization energy of Cu. When this relation holds (or approximately holds), the channel connecting the state of third ionization energy of Y and the state of second ionization energy of Cu can be opened. In this case of channel opening the Cooper pairs of d-valence electrons of Cu, the Cooper pairs of s-valence electrons of Y, and the bifurcation region of high-T_{c} superconductivity can be formed. We notice that x₀≈0.9846. Then YNi₅₍₁₋ₓ₎Cu₅ₓ comes into the range of superconductivity when x₂≦x≦x₀ for some x₂ such that 0<x₂<x₀<1. When (50) holds (or approximately holds) giving channel opening, the d-valence electrons of Cu in the Cu plane are in the basic state of second ionization energy and the d-valence electrons of Y are in the basic state of third ionization energy, and that other states are to be reached from these two states. Further the d-valence electrons of Cu in the Cu plane and the d-valence electron of Y are unified to occupy a sequence of states such that the d-valence electron of Cu in the Cu plane occupy the higher states while the d valence electron of Y occupies the lower state.

Thus, as MgB₂, the d-valence electrons of Cu are in the state of third ionization energy, the d-valence electron of Y is in the state of third ionization energy; and the s-valence electrons of Cu are in the state of first ionization energy, the s-valence electrons of Y is in the state of first ionization energy. Thus, the maximum value of the energy parameter |h_{Cu}| of the d-valence electrons of Cu is proportional to the third ionization energy of Cu, and the energy parameter |h_{Y}| of the s-valence electrons of Y is proportional to the first ionization energy of Y. Then, as La₁₋ₓCaₓCu₅, we have the following formula of T_{c} of YNi₅₍₁₋ₓ₎Cu₅ₓ:

$${k}_{B} {T}_{c} = κ = \frac{1}{\sqrt{3}} {Δ}_{YNiCu} \qquad ( 51 )$$

where Δ_{YNiCu}=h=75|h_{Cu}|+|h_{Y}| is the energy gap of the superconductivity of YNi₅₍₁₋ₓ₎Cu₅ₓ (The effect of s, d-valence electrons of Ni is omitted). Then from (51) we can compute the highest critical temperature T_{c} of YNi₅₍₁₋ₓ₎Cu₅ₓ which is upped to:

T_{c}≈525.43K (Computed T_{c} of YNi₅₍₁₋ₓ₎Cu₅ₓ) (52)

We may use other transition elements such as Co to replace the element Ni. In this case we have the intermetallic YCo₅₍₁₋ₓ₎Cu₅ₓ with x₀≈0.9. The critical temperature can be upped to T_{c}≈525.43K.

Let us then consider the case of Ni as the main part (instead of the above case of Cu as the main part) for YNi₅₍₁₋ₓ₎Cu₅ₓ. To this end let us write this intermetallic in the form YNi_{5y}Cu_{5(1-y)} (0≦y≦1). Then let us consider the following function for doping mechanism:

g(y)=1980−3555(1−y) (53)

where 1980 kJ/mol and 3555 kJ/mole are approximately the third ionization energies of Y and Cu respectively. This function gives the relation that the increasing of y gives the increasing of h. Then we set the following relation of the degenerate state of channel opening:

g(y₀)=1980−3555(1−y₀)=1753_{y}_{₀} (54)

for some y₀ (0<y₀<1) where 1753 kJ/mol is approximately the second ionizationy energy of Ni. When this relation holds (or approximately holds), the channel connecting the state of third ionization energy of Y and the state of second ionization energy of Ni (for the high-T_{c} superconductivity given by the Ni(Cu) plane) can be opened. Then, the rest is similar to LaNi₅₍₁₋ₓ₎Cu₅ₓ (0≦x≦1) with La replaced by Y and x replaced by y. Thus we have the the following formula of T_{c} of YNi_{5y}Cu_{5(1-y)}:

$${k}_{B} {T}_{c} = κ = \frac{1}{\sqrt{3}} {Δ}_{YNiCu} \qquad ( 55 )$$

where Δ_{YNiCu}=h=60|h_{Ni}|+15|h_{Ni1}|+|h_{Y}| is the energy gap of superconductivity of YNi_{5y}Cu_{5(1-y)} (when Ni instead of Cu is the main part). Then from (55) we can compute the critical temperature T_{c} of YNi_{5y}Cu_{5(1-y)} which is upped to:

T_{c}≈423.21K (Computed T_{c} of YNi_{5y}Cu_{5(1-y)}) (56)

### EXAMPLE 11

### CaCu₅-Type Intermetallic YNi₅₍₁₋ₓ₎Co₅ₓ

Let us consider an intermetallic YNi₅₍₁₋ₓ₎Co₅ₓ (0≦x≦1). We have that the intermetallics YCo₅ and YNi₅ are also of the CaCu₅-type. Thus YNi₅₍₁₋ₓ₎Co₅ₓ can be formed in the CaCu₅-type with Ca corresponding to Y and Cu corresponding to Ni₅₍₁₋ₓ₎Co₅ₓ. Then let us consider the following function for doping mechanism:

f(x)=1980−3232(1−x) (57)

where 1980 kJ/mol and 3232 kJ/mole are approximately the third ionization energies of Y and Co respectively. This function gives the relation that the increasing of x gives the increasing of h. Then we set the following relation of the degenerate state of channel opening:

f(x₀)=1980−3232(1−x₀)=1753x₀ (58)

for some x₀ (0<x₀<1) where 1753 kJ/mol is approximately the second ionization energy of Ni. When this relation holds (or approximately holds), the channel connecting the state of third ionization energy of Y and the state of second ionization energy of Ni can be opened. In this case of channel opening the Cooper pairs of s, d-valence electrons of Ni, the Cooper pairs of s valence electrons of Y, and the bifurcation region of high-T_{c} superconductivity can be formed. When (58) holds (or approximately holds) giving channel opening, the d-valence electrons of Ni in the Ni(Co) plane are in the basic state of second ionization energy of Ni and the d valence electrons of Y are in the basic state of third ionization energy of Y, and that other states are to be reached from these two states. Further the d-valence electrons of Ni in the Ni(Co) plane and the d valence electron of Y are unified to occupy a sequence of states such that the d-valence electrons of Ni in the Ni(Co) plane occupy the higher states while the d-valence electron of Y occupies the lower state.

Thus, the d-valence electrons of Ni are in the basic state of third ionization energy of Ni, the d-valence electron of Y is in the state of third ionization energy of Y; and the s-valence electrons of Ni are in the basic state of first ionization energy of Ni, the s-valence electrons of Y are in the basic state of first ionization energy. Thus, the maximum value of the energy parameter |h_{Ni}| of the d-valence electrons of Ni is proportional to the third ionization energy of Ni, the maximum value of the energy parameter |h_{Ni1}| of the s-valence electrons of Ni is proportional to the first ionization energy of Ni; and the energy parameter |h_{Y}| of the s-valence electrons of Y is proportional to the first ionization energy of Y. Then, as LaNi₅₍₁₋ₓ₎Cu₅ₓ, we have the following formula of T_{c} of YNi₅ₓCog₅₍₁₋ₓ₎:

$${k}_{B} {T}_{c} {=}^{′} κ = \frac{1}{\sqrt{3}} {Δ}_{YNiCo} \qquad ( 59 )$$

where Δ_{YNiCo}=h=60|h_{Ni}|+15|h_{Ni1}|+|h_{Y}| is the energy gap of the superconductivity of YNi₅ₓCo₅₍₁₋ₓ₎where the coefficients 15, 60=4.15 are from the

$$4 = \frac{8}{2}$$

for the eight d-valence electrons of the Ni, and the 15 for the fifteen Ni(Co) atoms of the cluster of Ni(Co) atoms in a unit cell. (For simplicity we have simplified the effect of s, d-valence electrons of Co for Δ_{YNiCo}).

We have |h_{Ni}|≈ξ3393 kJ/mol, |h_{Ni1}|≈ξ736.7 kJ/mol and |h_{Y}|≈ξ600 kJ/mol where 736.7 kJ/mol and 3393 kJ/mol are approximately the first and third ionization energies of Ni. Then from (59) we can compute the highest critical temperature T_{c} of YNi₅ₓCo₅₍₁₋ₓ₎ which is upped to:

T_{c}≈423.21K (Computed T_{c} of YNi₅ₓCO₅₍₁₋ₓ₎) (60)

The rare earth elements or Y of all the above CaCu₅-type superconductors may be replaced by the mixtures of rare earth elements such as Mm.

### EXAMPLE 12

### CaCu₅-Type Intermetallic Sr₁₋ₓCaₓCu₅

Let us consider an intermetallic Sr₁₋ₓCaₓCu₅ (0≦x≦1). This intermetallic is similar to the above intermetallic Sr₁₋ₓCaₓGa₂ with Ga₂ replaced by Cu₅, and is a special case of the above CaCu₅-type intermetallic R₁₋ₓAₓCu₅ with x=1 (A denotes a mixture of Ca and Sr). We have that CaCu₅ and SrCu₅ can be formed in the CaCu₅-type phase. Thus Sr₁₋ₓCaₓCu₅ can also be formed in the CaCu₅-type phase. For the doping mechanism of superconductivity let us consider the following function:

f(x)=5500(1−x)+6491x (61)

where 6491 kJ/mol and 5500 kJ/mole are approximately the fourth ionization energies of Ca and Sr respectively. This function gives the relation that the increasing of x gives the increasing of h. Then we set the following relation of the degenerate state of channel opening:

f(x₀)=5500(1−x₀)+6491x₀=5536 (62)

for some x₀ (0<x₀<1) where 5536 kJ/mol is approximately the fourth ionization energy of Cu. When this relation holds (or approximately holds), the channel connecting the two states of fourth ionization energy of Sr and Cu can be opened. This channel opening gives a freedom of electric current with a direction orthogonal to the Cu plane. From this freedom of electric current, the Cooper pairs of the 3s, 3p-level electrons of Cu and the 4s, 4p-level electrons of Sr can be formed. Thus this channel opening gives the 3D region of conventional superconductivity. From this 3D conventional superconductivity we have the existence of quasi-2D bifurcation region of high-T_{c} superconductivity given by the Cu plane. We notice that x₀≈0.0363. Thus Sr₁₋ₓCaₓCu₅ comes into the range of superconductivity when x₀≦x≦x₁ for some x₁ such that x₀<x₁<1. When (62) holds (or approximately holds) giving channel opening, the 3s, 3p-level electrons of Cu in the Cu plane are in the basic state of fourth ionization energy and the 4s, 4p-level electrons of Sr are in the basic state of fourth ionization energy, and that other states are to be reached from these two states. Further the 3s, 3p-level electrons of Cu and the 4s, 4p-level electrons of Sr are unified to occupy a sequence of states such that the 3s, 3p-level electrons of Cu in the Cu plane occupy the higher states while the 4s, 4p-level electrons of Sr occupy the lower states. Thus, the 3s, 3p-level electrons of Cu are in the state of fifth ionization energy of Cu; and the 4s, 4p-level electrons of Sr are in the basic state of fourth ionization energy. The 4s, 4p-level electrons of Sr in the basic state of fourth ionization energy are in the opened channel of 3D superconductivity, while the 3s, 3p-level electrons of Cu in the state of fifth ionization energy are for the quasi-2D high-T_{c} superconductivity of the Cu plane. Then when (62) holds giving channel opening the Cooper pairs of the s, p-valence electrons of Sr can also be formed. These s-valence electrons of Sr are in the basic state of first ionization energy (and can be in the states of third and second ionization energies of valence electrons respectively).

Thus, the energy parameter |h_{Cu5}| of the 3s, 3p-level electrons of Cu is proportional to the fifth ionization energy of Cu; the energy parameter |h_{Sr4}| of the 4s, 4p-level electrons of Sr is proportional to the fourth ionization energy of Sr; and the energy parameter |h_{Sr}| of the s-valence electrons of Sr is proportional to the first ionization energies Sr respectively (when the s-valence electrons of Sr is in the basic state of first ionization energy). Then, as Sr₁₋ₓCaₓGa₂, we have the following formula of T_{c} of Sr₁₋ₓCaₓCu₅:

$${k}_{B} {T}_{c} = κ = \frac{1}{\sqrt{3}} {Δ}_{CaSrCu} \qquad ( 63 )$$

where Δ_{CaSrCu}=h=60|h_{Cu5}+4|h_{Sr4}|+|h_{Sr}| is the energy gap of superconductivity of Sr₁₋ₓCaₓCu₅ where the coefficients 4, 60=4.15 are from the

$$4 = \frac{8}{2}$$

for the eight 3s, 3p-level electrons of the Cu or the eight 4s, 4p-level electrons of the Sr, and the 15 for the fifteen Cu atoms of the CaCu₅-type structure, as the above case R₁₋ₓAₓCu₅ with x<1.

We have |h_{Cu5}|≈ξ7700 kJ/mol, |h_{Sr}|≈ξ549.5 kJ/mol and |h_{Sr4}|≈ξ5500 kJ/mol where 7700 kJ/mol is approximately the fifth ionization energy of Cu, and 549.5 kJ/mol is approximately the first ionization energy of Sr. Then from (63) we can compute the highest critical temperature T_{c} of Sr₁₋ₓCaₓCu₅ which is upped to:

T_{c}≈952.7K (Computed T_{c} of Sr₁₋ₓCaₓCu₅) (64)

Similar to the above intermetallic R₁₋ₓAₓCu₅, we may generally replace Cu with TM=Ni, Co, Zn and the mixture of Cu, Ni, Co, Zn to construct the intermetallic Sr₁₋ₓCaₓTM₅. Then we notice that this intermetallic R₁₋ₓAₓCu₅ (0<x<1) where R denotes a rare earth element including the element Y and the mixture thereof may have two cases of high-T_{c} superconductivity: a case is the case of the Cu d-electron (from the effect of both A and R) and the other case is the case of the Cu s, p-electron (from the effect of A only or from the effect of both A and R). When both cases of superconductivity appear at some doping, the effects of superconductivity of these two cases can be combined. From this combination of effects of superconductivity we can have a larger critical current consisting of d-electrons and s, p-electrons and a higher critical temperature T. As an example let us consider the intermetallic La₁₋ₓSr_{x(1-y)}Ca_{xy}Cu₅ (0<x, y<1). Let the doping parameters x, y be such that

$$\frac{( 1 - x )}{1 + x + xy} 1850.3 + \frac{xy}{1 - x + xy} 4912.4 = 1957.9 \qquad ( 65 )$$

(1−y)5500+y6491=5536

When this relation of the degenerate state of channel opening holds (or approximately holds), the s, p-channel connecting the two states of fourth ionization energy of the 3s, 3p-electrons of Cu and the 4s, 4p-electrons of Sr can be opened, and also the d-channel connecting the two states of ionization energy of the 3d-electrons of Cu and the 5d-electron of La can be opened. This two-channel-opening gives a freedom of electric current with a direction orthogonal to the Cu plane. From this freedom of electric current, the Cooper pairs of the 3s, 3p, 3d-electrons of Cu and the 4s, 4p-electrons of Sr can be formed. Then, this two-channel-opening can give two types of high-T_{c} superconductivity: the s, p-electron superconductivity and the d-electron superconductivity. This combination of s, p-electron superconductivity and d-electron superconductivity can give larger critical current and higher critical temperature T_{c}.

A General Form of CaCu₅-Type Intermetallics

We notice that the hexagonal unit cells of the above examples of CaCu₅-type intermetallics are with a large cluster of superconducting electrons, thus these CaCu₅-type intermetallics are with high critical current density of superconducting current. Also we notice that the doping of the above CaCu₅-type (or AlB₂-type) intermetallics gives the degenerate state of channel opening for superconductivity. Thus the doping of the above CaCu₅-type (or AlB₂-type) intermetallics has the effect of introducing pinning centers of superconducting current to these CaCu₅-type (or AlB₂-type) intermetallics.

We may apply more dopings to form more CaCu₅-type intermetallics. For superconductivity these dopings must give the degenerate state of channel opening. By more dopings we have the following form of intermetallic which includes the above examples of CaCu₅-type intermetallics:

R₁₋ₓAₓ(TM_{5(1-y)}M_{y})_{1+z} (66)

where 0≦y≦y₀=0.02, 0≦z≦z₀=0.01 for some small parameters y₀, z₀ (The doping parameters y₀, z₀ are small to keep the CaCu₅-type phase); TM=Cu, Ni, Co, Zn, and M is a mixture of elements Ti, Cr, Mn, Fe, Co, Zr, Nb, Mo, Hf, Ta, W, Ga, In, Al, Si, Ge, Sn. These elements are with states of second or third ionization energies quite close to that of R or TM. Thus for some chosen M, y and z, this intermetallic can give the degenerate state of channel opening.

From the properties of the CaCu₅-type intermetallic (66) we have a process of manufacturing CaCu₅-type superconductors, as follows. The powders of constituent of a CaCu₅-type intermetallic (66) are first mixed in accordance with the composition. Then the mixture of powders are melted in an induction furnace under argon atmosphere at a temperature between 800 C. and 1600 C. After the materials are melted, the melt is maintained at the same temperature for 20 minutes to 1 hour to achieve better homogeneity. The melt is then poured into a mold and under pressure between the ambient pressure and 6 GPa cooled down for solidification and for the formation of said CaCu₅ phase. After cooling, under pressure between ambient pressure and 6 GPa the resulting CaCu₅-type ingot is annealed in a furnace at a temperature between 600° C. and 1200° C. in an argon atmosphere for 0.5 to 24 hours to achieve the state that the 3d-level (or 3s, 3p-level) electrons of TM=Cu, Ni, Co, Zn and the mixture thereof are in the degenerate state of channel opening. This gives the bulk form of the superconductor R₁₋ₓAₓ(TM_{5(1-y)}M_{y})_{1+z}.

From the properties of the CaCu₅-type superconductors, we have the following process of manufacturing these CaCu₅-type superconductors in wire form:
preparing and mixing powders of the constituent R and A of said CaCu₅-type superconductor in accordance with the composition 0.02≦x_{c}≦1 where A is for the doping of superconductivity and for pinning centers of critical currents;
preparing and mixing powders of the constituents TM₅ and M of said CaCu₅-type superconductor in accordance with the composition 0≦y≦0.02 where M is for pinning centers of critical currents;
preparing said powders of the constituent consisting of R and A and said powders of the constituent consisting of TM₅ and M in accordance with the composition 1:1+z where 0≦z≦0.01;
mixing said powders of the constituents of said CaCu₅-type superconductor;
melting said mixture of powders of constituents of said CaCu₅-type superconductor in an induction furnace under argon atmosphere at a temperature between 800° C. and 1600° C.;
maintaining said melt at a temperature between 800° C. and 1600° C. for about 20 minutes to 1 hour to achieve better homogeneity;
under pressure between the ambient pressure and 6 GPa casting said melt in an argon atmosphere or in a vacuum to form an ingot with said CaCu₅ phase;
hot rolling or drawing said ingot to a wire form with a specified diameter or with a specified shape such-as a tape shape;
maintaining the superconducting layers of said ingot in parallel with the surface of said ingot in case said ingot is in tape-shaped wire form during casting and drawing of forming said ingot;
under pressure between the ambient pressure and 6 GPa annealing said CaCu₅-type ingot in wire form at a temperature between 600° C. and 1200 C. in an argon atmosphere for 0.5 to 24 hours to achieve the state that the 3d-level electrons of G are in the degenerate state of channel opening;
cooling said ingot in wire form down to room-temperature to get a CaCu₅-type superconductor in wire form.

There exist various methods of manufacturing thin films such as the chemical vapor deposition (CVD), the method of magnetron sputtering, the method of molecular beam epitaxy (MBE), and the method of pulsed laser position (PLD). By using these methods for the above CaCu₅-type (or AlB₂-type) superconductors and from the properties and structure of these CaCu₅-type (or AlB₂-type) superconductors, we have processes of manufacturing thin films of these CaCu₅-type (or AlB₂-type) superconductors. Since these CaCu₅-type (or AlB₂-type) superconductors are with the hexagonal crystal structure, besides the conventional substrates for depositing thin films such as the silicon substrate, substrates with hexagonal texture are suitable as the substrate for depositing thin films of these CaCu₅-type (or AlB₂-type) superconductors. For example, when the CaCu₅-type intermetallics R₁₋ₓ_{ᵥ}Aₓ_{ᵥ}(TM_{5(1-xy)}M_{y})_{1+z} is in a state (which is superconductive or non-superconductive) for some doping xᵥ, then this CaCu₅-type intermetallics can be as a substrate for depositing thin film of CaCu₅-type superconductor with a doping x, which is different from xᵥ.

From the properties of CaCu₅-type intermetallics R₁₋ₓ_{ᵥ}Aₓ_{ᵥ}TM_{5(1-y)}M_{y}, a process of manufacturing said CaCu₅-type superconductor in thin film form comprises the following steps:
preparing a sintered bulk form of powder of the constituent R of said CaCu₅-type superconductor in accordance with the composition 0≦x_{c}≦1 as a target; and preparing a sintered bulk form of powder of the constituent A of said CaCu₅-type superconductor in accordance with the composition 0≦x_{c}≦1 as a target; or preparing a sintered bulk form of the mixture of powders of the constituents R and A of said CaCu₅-type superconductor in accordance with the composition 0≦x_{c}≦1 as a target;
preparing a sintered bulk form of the powder of the constituent TM of said CaCu₅-type superconductor in accordance with the composition 0≦y≦0.02 and 0≦z≦0.01 as a target; and preparing a sintered bulk form of the powder of the constituent M of said CaCu₅-type superconductor in accordance with the composition 0≦y≦0.02 and 0≦z≦0.01 where M is for pinning centers of critical currents as a target; or preparing a sintered bulk form of the mixture of powders of the constituents TM and M of said CaCu₅-type superconductor in accordance with the composition 0≦y≦0.02 and 0≦z≦0.01 as a target;
alternatively preparing a sintered bulk form of the mixture of powders of all the constituents of said CaCu₅-type superconductor in accordance with the composition as the only target;
alternatively preparing a bulk form of said CaCu₅-type superconductor as the only target;
preparing a substrate made of materials selected from the group consisting of silicon, quartz crystal, stainless steel, YSZ, SrTiO₃, Al₂O₃, ZrO₂, MgO; and AlB₂-type intermetallic such as Sr₁₋ₓ_{ᵥ}Caₓ_{ᵥ}AlSi, Gd₁₋ₓ_{ᵥ}Caₓ_{ᵥ}CuSi, La₁₋ₓ_{ᵥ}Baₓ_{ᵥ}CuGe, Mm₁₋ₓ_{ᵥ}Caₓ_{ᵥ}CuSi; and CaCu₅-type intermetallic R₁₋ₓ_{ᵥ}Aₓ_{ᵥ}(TM_{5(1-y)}M_{y})_{1+z} under some doping xᵥ (0≦xᵥ≦1);
sputtering or laser ablating or applying other methods on said targets to form thin film on said substrate;
under pressure between the ambient pressure and 6 GPa cooling said thin film for solidification with said CaCu₅ phase;
under pressure between the ambient pressure and 6 GPa annealing said CaCu₅-type thin film at a temperature between 600° C. and 1200° C. in an argon atmosphere for 0.5 to 24 hours to achieve the state that the 3d-level (or 3s, 3p-level) electrons of TM=Cu, Ni, Co, Zn and the mixture thereof are in the degenerate state of channel opening;
cooling said thin film down to room-temperature to get said CaCu₅-type superconductor in thin form deposited on said substrate.

A General Form of Intermetallics with Hexagonal Crystal Structure of Three Layers

We can express the above examples of CaCu₅-type and AlB₂-type superconductors into the following general form of intermetallics:

R_{1-x′}E_{(1-x″)x′}A_{x″x′}[(D_{m(1-x′″)}G_{mx′″})_{1-y}M_{y}]_{1+z} (67)

wherein R denotes rare earth elements (including Y) and mixture thereof, E and A denote alkaline earth elements and mixture thereof and E≠A when x′=1, such that said R, E, A elements are in the upper and lower layers of the hexagonal crystal structure of three layers of (67) and D=Cu, Ga, Al, Si, Ni, Co, Zn and G=Cu, Ga, Ge, Si, Ni, Co, Zn are elements in the middle layer forming a conducting layer and may also be in the upper and lower layers, and m=2 or 5, and x′, x″, x′″ are doping parameters such that 0≦x′≦1, 0.01≦x″≦0.9, 0≦x′″≦1; and M=Ti, Cr, Mn, Fe, Co, Zr, Nb, Mo, Hf, Ta, W, Al, Ga, In, Si, Ge, Sn and mixture thereof, and 0≦y≦0.02, 0≦z≦0.01.

When m=2 this intermetallics (67) is formed with the AlB₂-type crystal structure and when m=5 this intermetallics (67) is formed with the CaCu₅-type crystal structure. For this intermetallic (67) to be in the state of superconductivity, this intermetallic (67) is doped to be in the degenerate state of channel opening as specified in the above examples.

What is claimed is:

1. A method of composing high-T_{c} superconductors, said method comprising the steps of
synthesizing an intermetallic R_{1-x′}E_{(1-x″)x″}A_{x″x′}[(D_{m(1-x′″)}G_{mx′″})_{1-y}M_{y}]_{1+z} with a hexagonal crystal structure of three layers such as the AlB₂-type crystal structure and the CaCu₅-type crystal structure, wherein R denotes rare earth elements (including the element Y) and mixture thereof, E and A denote alkaline earth elements and mixture thereof and E≠A when x′−1, such that said R, E, A elements are in the upper and lower layers of said hexagonal crystal structure of three layers, and D=Cu, Ga, Al, Si, Ni, Co, Zn and G=Cu, Ga, Ge, Si, Ni, Co, Zn are elements in the middle layer forming a conducting layer and may also be in the upper and lower layers of said hexagonal crystal structure of three layers, and m=2 or 5 and x′, x″, x′″ are doping parameters such that 0≦x′≦1, 0.01≦x″≦0.9, 0≦x′″≦1; and M=Ti, Cr, Mn, Fe, Co, Zr, Nb, Mo, Hf, Ta, W, Al, Ga, In, Si, Ge, Sn and mixture thereof, and 0≦y≦0.02, 0≦z≦0.01.
doping said intermetallic at some values x′_{c}, x″_{c}, x′″_{c} of the parameters x′, x″, x′″ such that said intermetallic is in the degenerate state of channel opening.

2. The method of claim 1, wherein said two steps can be performed simultaneously instead of step by step.

3. The method of claim 1, wherein said intermetallic is of the form E_{1-x″}A_{x″}D_{m(1-x′″)}G_{mx′″} which is of the AlB₂-type crystal structure, wherein E=Sr, Ba and mixture thereof, and A=Ca, Sr and mixture thereof, E≠A, and D=Ga, Al, Si and mixture thereof, G=Ga, Si, Ge and mixture thereof, and m=2.

4. The method of claim 1, wherein said intermetallic is of the form R_{1-x′}E_{(1-x″)x′}A_{x″x′}D_{m(1-x′″)}G_{mx′″} which is of the AlB₂-type crystal structure, wherein R═La, Gd, Y or rare earth elements or mixture of rare earth elements, A=Ca, Sr, Ba and mixture thereof, and D=Cu, G=Si, Ge and mixture thereof, and m=2.

5. The method of claim 1, wherein said intermetallic is of the form R_{1-x′}E_{(1-x″)x′}A_{x″x′}D_{m(1-x′″)}G_{mx′″} which is of the CaCu₅-type crystal structure, wherein R═La, Gd, Y or rare earth elements or mixture of rare earth elements, E=Ca, Sr, Ba and mixture thereof, and A=Ca, Sr, Ba and mixture thereof, and D=Cu, Ni, Co, Zn and mixture thereof, G=Cu, Ni, Co, Zn and mixture thereof, and m=5.

6. The method of claim 1, wherein a process of manufacturing said CaCu₅-type or AlB₂-type superconductor comprising the steps of
preparing and mixing powders of the constituents R, E and A of said CaCu₅-type or AlB₂-type superconductor in accordance with the composition 0≦x′_{c}≦1, 0.01≦x″_{c}≦0.9;
preparing and mixing powders of the constituents D and G of said CaCu₅-type or AlB₂-type superconductor in accordance with the composition 0≦x′″_{c}≦1;
preparing and mixing powders of said constituent consisting of D and G and the constituent M of said CaCu₅-type or AlB₂-type superconductor in accordance with the composition 0≦y≦0.02;
preparing said powders of the constituent consisting of R, E and A and said powders of the constituent consisting of D, G and M in accordance with the composition 1:1+z where 0≦z≦0.01;
mixing said powders of the constituents of said CaCu₅-type or AlB₂-type superconductor;
melting said mixture of powders of constituents of said CaCu₅-type or AlB₂-type superconductor in an induction furnace under argon atmosphere at a temperature between 300° C. and 1600° C.;
maintaining said melt at a temperature between 300° C. and 1600° C. for about 20 minutes to 1 hour to achieve better homogeneity;
under pressure between the ambient pressure and 16 GPa cooling said melt for solidification with said CaCu₅-type phase or AlB₂-type phase;
under pressure between the ambient pressure and 16 GPa annealing the resulting CaCu₅-type or AlB₂-type ingot at a temperature between 300° C. and 1200° C. in an argon atmosphere for 0.5 to 24 hours to achieve the state that the 3d-level (or 2s, 2p-level or 3s, 3p-level) electrons of D or G are in the degenerate state of channel opening;
cooling said ingot down to room-temperature to get said CaCu₅-type or AlB₂-type superconductor in bulk form.

7. The method of claim 1, wherein a process of manufacturing said CaCu₅-type or AlB₂-type superconductor in wire form comprising the steps of
preparing and mixing powders of the constituents R, E and A of said CaCu₅-type or AlB₂-type superconductor in accordance with the composition 0≦x′_{c}≦1, 0.01≦x″_{c}≦0.9;
preparing and mixing powders of the constituents D and G of said CaCu₅-type or AlB₂-type superconductor in accordance with the composition 0≦x′″_{c}≦1;
preparing and mixing powders of the constituent consisting of D and G and the constituent M of said CaCu₅-type or AlB₂-type superconductor in accordance with the composition 0≦y≦0.02;
preparing said powders of the constituent consisting of R, E and A and said powders of the constituent consisting of D and G and the constituent M in accordance with the composition 1:1+z where 0≦z≦0.01;
mixing said powders of the constituents of said CaCu₅-type or AlB₂-type superconductor;
melting said mixture of powders of constituents of said CaCu₅-type or AlB₂-type superconductor in an induction furnace under argon atmosphere at a temperature between 300° C. and 1600° C.;
maintaining said melt at a temperature between 300° C. and 1600° C. for about 20 minutes to 1 hour to achieve better homogeneity;
under pressure between the ambient pressure and 16 GPa casting said melt in an argon atmosphere or in a vacuum to form an ingot with said CaCu₅-type or AlB₂-type phase;
hot rolling or drawing said ingot to a wire form with a specified diameter or with a specified shape such as a tape shape;
maintaining the superconducting layers of said ingot in parallel with the surface of said ingot in case said ingot is in tape-shaped wire form during casting and drawing of forming said ingot;
under pressure between the ambient pressure and 16 GPa annealing said CaCu₅-type or AlB₂-type ingot in wire form at a temperature between 300° C. and 1200° C. in an argon atmosphere for 0.5 to 24 hours to achieve the state that the 3d-level (or 2s, 2p-level or 3s, 3p-level) electrons of D or G are in the degenerate state of channel opening;
cooling said ingot in wire form down to room-temperature to get a CaCu₅-type or AlB₂-type superconductor in wire form.

8. The method of claim 1, wherein a process of manufacturing said CaCu₅-type or AlB₂-type superconductor in thin film form comprising the steps of
preparing a sintered bulk form of powder of the constituent R of said CaCu₅-type or AlB₂-type superconductor in accordance with the composition 0≦x′_{c}≦1 as a target; and
preparing a sintered bulk form of powder of the constituent E of said CaCu₅-type or AlB₂-type superconductor in accordance with the composition 0≦x′_{c}≦1 and 0.01≦x″_{c}≦0.9 as a target; and
preparing a sintered bulk form of powder of the constituent A of said CaCu₅-type or AlB₂-type superconductor in accordance with the composition 0≦x′_{c}≦1 and 0.01≦x″_{c}≦0.9 as a target; and
preparing a sintered bulk form of powder of the constituent D of said CaCu₅-type or AlB₂-type superconductor in accordance with the composition 0<x′″_{c}≦1 as a target; and
preparing a sintered bulk form of powder of the constituent G of said CaCu₅-type or AlB₂-type superconductor in accordance with the composition 0<x′″_{c}≦1 as a target;
preparing a sintered bulk form of the powder of said constituent consisting of D and G of said CaCu₅-type or AlB₂-type superconductor in accordance with the composition 0≦y≦0.02 and 0≦z≦0.01 as a target; and preparing a sintered bulk form of the powder of the constituent M of said CaCu₅-type or AlB₂-type superconductor in accordance with the composition 0≦y≦0.02 and 0≦z≦0.01;
preparing a substrate made of materials selected from the group consisting of silicon, quartz crystal, stainless steel, YSZ, SrTiO₃, Al₂O₃, ZrO₂, MgO; and AlB₂-type intermetallic such as Sr₁₋ₓ_{ᵥ}Caₓ_{ᵥ}AlSi, Gd₁₋ₓ_{ᵥ}Caₓ_{ᵥ}CuSi, La_{1-z}_{ᵥ}Baₓ_{ᵥ}CuGe, Mm₁₋ₓ_{ᵥ}Caₓ_{ᵥ}CuSi; and CaCu₅-type intermetallic R₁₋ₓ_{ᵥ}Aₓ_{ᵥ}(G_{1-y}M_{y})_{1+z} under some doping xᵥ (0≦xᵥ≦1);
sputtering or laser ablating or applying other methods on said targets to form thin film on said substrate;
under pressure between the ambient pressure and 16 GPa cooling said thin film for solidification with said CaCu₅-type or AlB₂-type phase;
under pressure between the ambient pressure and 16 GPa annealing said CaCu₅-type or AlB₂-type thin film at a temperature between 300° C. and 1200° C. in an argon atmosphere for 0.5 to 24 hours to achieve the state that the 3d-level (or 2s, 2p-level or 3s, 3p-level) electrons of D or G are in the degenerate state of channel opening;
cooling said thin film down to room-temperature to get said CaCu₅-type or AlB₂-type superconductor in thin form deposited on said substrate.

9. The method of claim 8, wherein said sintered bulk forms of powders of the constituents R, E, A, D, G and M as targets may be replaced by a bulk form of said CaCu₅-type or AlB₂-type superconductor as the single target.

10. The method of claim 8, wherein said sintered bulk forms of powders of the constituents R, E, A, D, G and M as targets may be replaced by a sintered bulk form of the mixture of powders of the constituents R, E, A, D, G and M of said CaCu₅-type or AlB₂-type superconductor in accordance with the composition as the single target.
